(19) United States
(12) Patent Application Publication
(10) Pub. No.: US 2007/0278587 A1
(43) Pub. Date: Dec. 6, 2007

(54) Semiconductor device and manufacturing method thereof

(76) Inventors: Tomonori Aoyama, Yokohama-Shi (JP); Tomohiro Saito, Yokohama-Shi (JP); Katsuyuki Sekine, Yokohama-Shi (JP); Kazuaki Nakajima, Tokyo (JP); Motoyuki Sato, Tsukuba-Shi (JP); Takuya Kobayashi, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/798,068

(22) Filed: May 10, 2007

(30) Foreign Application Priority Data
May 15, 2006 (JP) 2006-135550
Jan. 12, 2007 (JP) 2007-004917

(51) Int. Cl. H01L 29/94

(52) U.S. Cl. 257/369

(57) ABSTRACT

This disclosure concerns a semiconductor device comprising a semiconductor substrate; a gate dielectric film provided on the semiconductor substrate and containing Hf, Si, and O or containing Zr, Si and O; a gate electrode of an n-channel FET provided on the gate dielectric film, the gate electrode being made of nickel silicide containing nickel at a higher content than silicon; an aluminum layer provided at a bottom portion of the gate electrode of the n-channel FET; and a gate electrode of a p-channel FET provided on the gate dielectric film, the gate electrode being made of nickel silicide containing nickel at a higher content than silicon.

### CROSS-REFERENCE TO RELATED APPLICATION

This application is based upon and claims the benefit of priority from the prior Japanese Patent Applications No. 2006-135550, filed on May 15, 2006 and No. 2007-4917, filed on Jan. 12, 2007, the entire contents of which are incorporated herein by reference.

### BACKGROUND OF THE INVENTION

1. Field of the Invention

The present invention relates to a semiconductor device and a semiconductor device manufacturing method.

2. Related Art

In recent years, adoption of a high dielectric constant material in gate dielectric films has been proposed to reduce EOT (Equivalent Oxide Thickness) of the gate dielectric films (for example, 1.3 nm or less) and to suppress leakage current. The high dielectric constant material is, for example, a metal oxide film having a relative permittivity higher than a silicon oxide film, a metal silicate film having a relative permittivity higher than a silicon oxide film, or nitride films of these materials.

If a high dielectric constant material is used for the gate dielectric film, a threshold voltage of FET (Field-Effect Transistor) shifts. In an n-channel MISFET (Metal-Insulator Semiconductor FET), the threshold voltage can be adjusted to a relatively appropriate value by doping phosphorus or arsenic in a polysilicon gate electrode. On the other hand, in a p-channel MISFET, even if boron or boron fluoride is doped in a polysilicon gate electrode, it is difficult to adjust the threshold voltage to an appropriate value since the threshold voltage has been greatly shifted in the negative direction. In addition, in a p-channel MISFET in which a high dielectric constant material is used for the insulation film, a capacitance in the inversion condition decreases. In such a p-channel MISFET that the threshold voltage greatly shifts in the negative direction and capacitance in the inversion condition is small, there is a problem that a desirable drain current cannot be obtained.

To counter decrease of the capacitance in the inversion condition, a technique in which metal is used as a material of the gate electrode instead of the polysilicon gate electrode has been devised. The metal includes not only a simple substance of metal and an alloy but also nitride or silicide of these materials. Particularly, a full silicide gate electrode for which nickel silicide is used has no temperature constraint in a process of forming the gate dielectric film; therefore, a good gate dielectric film can be formed. Furthermore, such a full silicide gate electrode is not depleted, a large inversion capacitance can be obtained.

However, there is a problem that the threshold voltages of both the n-channel MISFET and the p-channel MISFET that are provided with the full silicide gate electrode for which nickel silicide is used shifts from an appropriate value.

### SUMMARY OF THE INVENTION

A semiconductor device according to the present invention comprises a semiconductor substrate; a gate dielectric film provided on the semiconductor substrate and containing Hf, Si, and O or containing Zr, Si and O; a gate electrode of an n-channel FET provided on the gate dielectric film, the gate electrode being made of nickel silicide containing nickel at a higher content than silicon; an aluminum layer provided at a bottom portion of the gate electrode of the n-channel FET; and a gate electrode of a p-channel FET provided on the gate dielectric film, the gate electrode being made of nickel silicide containing nickel at a higher content than silicon.

A manufacturing method of a semiconductor device according to the present invention comprises forming a gate dielectric film containing Hf, Si, and O or containing Zr, Si and O on a semiconductor substrate; depositing a gate electrode material made of polysilicon or amorphous silicon on the gate dielectric film; forming a gate electrode by processing the gate electrode material into a gate electrode pattern; depositing a nickel film on the gate electrode; siliciding the gate electrode with the nickel film so that a composition of the gate electrode becomes Ni_{X}Si_{Y} where X>Y; depositing aluminum on the gate electrode in an n-channel FET formation region; and forming an aluminum layer at a bottom portion of the gate electrode of an n-channel FET by causing the aluminum to segregate to the bottom portion of the gate electrode in the n-channel FET formation region by a thermal processing.

A manufacturing method of a semiconductor device according to the present invention comprises forming a gate dielectric film containing Hf, Si, and O or containing Zr, Si and O on a semiconductor substrate; depositing a gate electrode material made of polysilicon or amorphous silicon on the gate dielectric film; forming a gate electrode by processing the gate electrode material into a gate electrode pattern; depositing a nickel film on the gate electrode; siliciding the gate electrode with the nickel film so that a composition of the gate electrode becomes Ni_{X}Si_{Y} where X>Y; implanting aluminum on the gate electrode in an n-channel FET formation region; and forming an aluminum layer at a bottom portion of the gate electrode of an n-channel FET by causing the aluminum to segregate to the bottom portion of the gate electrode in the n-channel FET formation region by a thermal processing.

### BRIEF DESCRIPTION OF THE DRAWINGS

FIGS. 1 to 22 are cross-sections showing a manufacturing method of a semiconductor device according to a first embodiment of the present invention;

FIG. 23 is a graph showing a work function of the gate electrodes of the p-channel MISFET and the n-channel MISFET according to the first embodiment;

FIGS. 24 to 42 are cross-sections showing a manufacturing method of a semiconductor device according to a second embodiment of the present invention;

FIG. 43 is a graph showing a work function of the gate electrodes of the p-channel MISFET and the n-channel MISFET according to the second embodiment;

FIGS. 44 to 58 are cross-sections showing a manufacturing method of a semiconductor device according to a fourth embodiment of the present invention; and

FIGS. 59 to 63 are cross-sections showing a manufacturing method of a semiconductor device according to a fifth embodiment of the present invention.

### DETAILED DESCRIPTION OF THE INVENTION

Embodiments of the present invention will be explained below with reference to the accompanying drawings. The present invention is not limited to the embodiments.

### First Embodiment

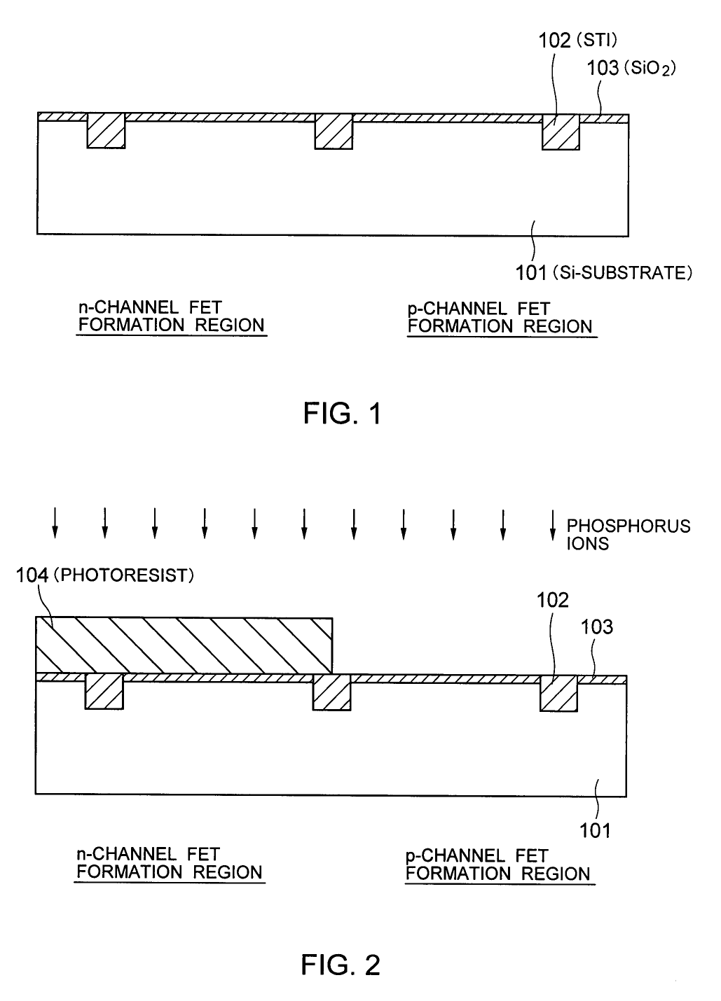

FIGS. 1 to 22 are cross-sections showing a manufacturing method of a semiconductor device according to a first embodiment of the present invention. The semiconductor device manufactured according to the first embodiment includes a gate electrode formed with Ni₂Si.

First, as shown in FIG. 1, trenches are formed in a silicon substrate 101, and by filling the trenches with silicon oxide film, STIs (Shallow Trench Isolations) 102 are formed. A sacrificial oxide film 103 is formed on a surface of the silicon substrate 101.

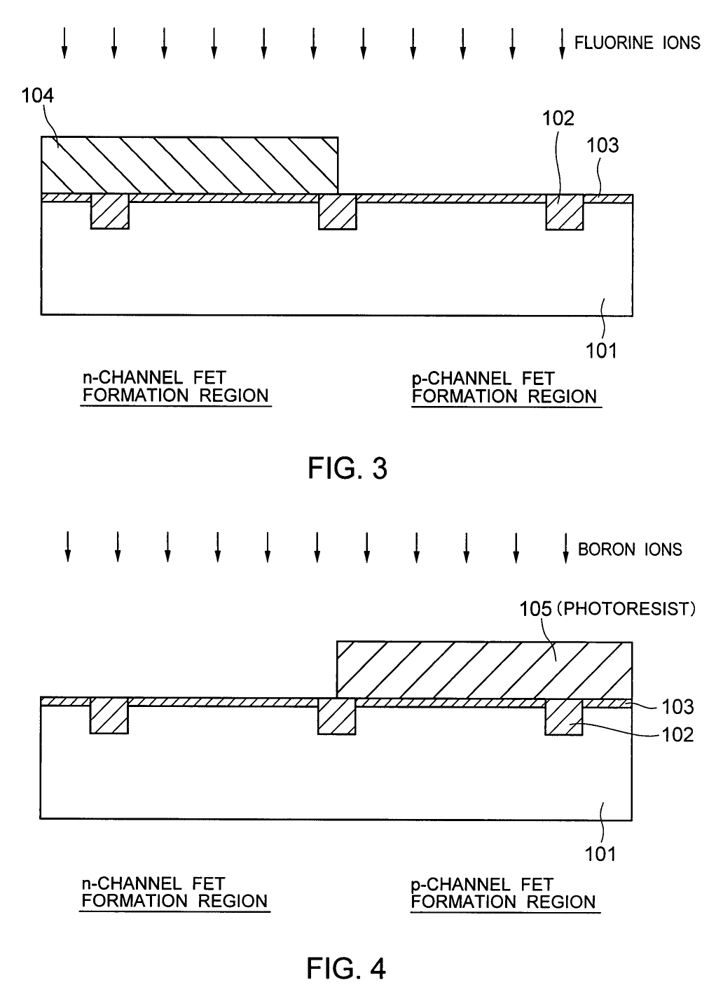

Next, as shown in FIG. 2, an n-channel MISFET formation region is coated with a photoresist 104. To form an n-type well, an n-type impurity (for example, phosphorus) is ion-implanted in a p-channel MISFET formation region. Implantation of phosphorus is also carried out for the purpose of adjustment of the threshold voltage of a transistor besides formation of an impurity diffusion layer. For fine adjustment of the threshold voltage of a transistor, boron ion or indium ion is implanted in some cases. Subsequently, as shown in FIG. 3, fluorine ion is implanted in a surface of the p-channel MISFET formation region.

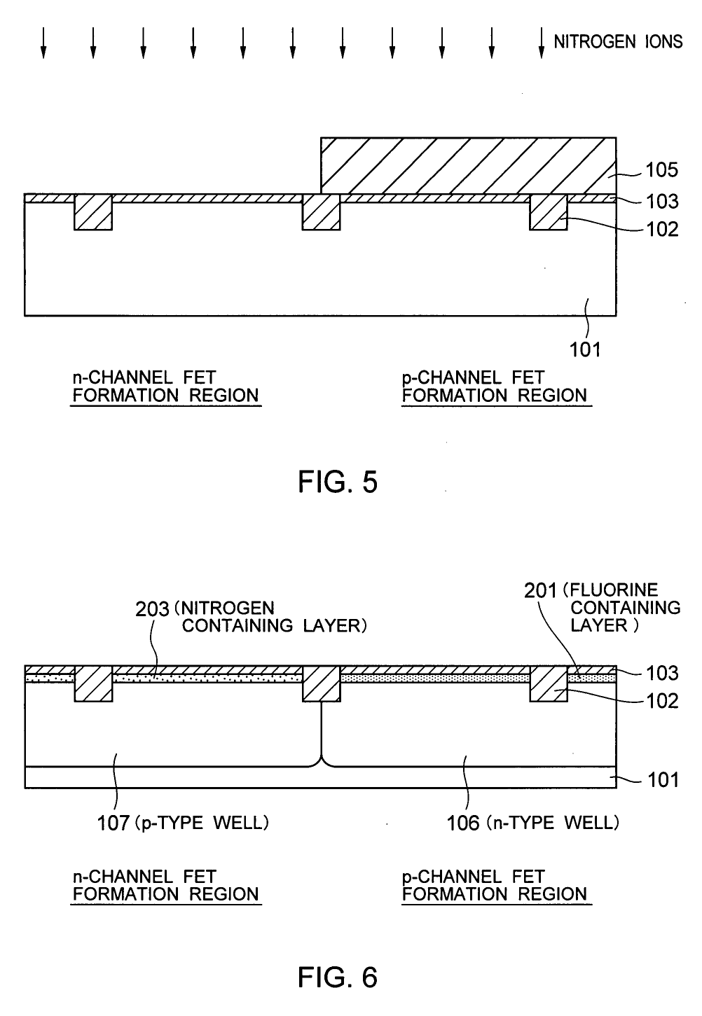

Next, as shown in FIG. 4, the p-channel MISFET formation region is coated with a photoresist 105. To form a p-type well, a p-type impurity (for example, boron) is ion-implanted in the n-channel MISFET formation region. Implantation of boron is also carried out for adjustment of the threshold voltage of a transistor besides formation of an impurity diffusion layer. For fine adjustment of the threshold voltage of a transistor, arsenic ion or phosphorus ion is implanted in some cases. Subsequently, as shown in FIG. 5, nitrogen ion is implanted in a surface of the n-channel MISFET formation region. By thermal diffusion of these impurities, an n-type well 106, a p-type well 107, a fluorine containing layer 201, and a nitrogen containing layer 203 are formed as shown in FIG. 6. The fluorine containing layer 201 and the nitrogen containing layer 203 are formed at surface portions of the n-type well 106 and the p-type well 107, respectively. The fluorine containing layer 201 has a function of shifting the flat band potential in the positive direction and the nitrogen containing layer 203 has a function of shifting the flat band potential in the negative direction. If the threshold voltage is enough low in an absolute value, the fluorine containing layer 201 and the nitrogen containing layer 203 are not required.

The sacrificial oxide film 103 is removed using an NH₄F solution. Immediately after cleaning the surface with a dilute hydrofluoric acid solution of 0.5% to 5%, a silicon oxide film 108 of approximately 0.5 nm to 0.8 nm is formed in an oxygen atmosphere. Furthermore, a hafnium silicon oxide film (HfSiO film) having a film thickness of approximately 2.0 nm is formed on the silicon substrate 101 using tetrakisdiethylaminohafnium, diethylsilane, and oxygen.

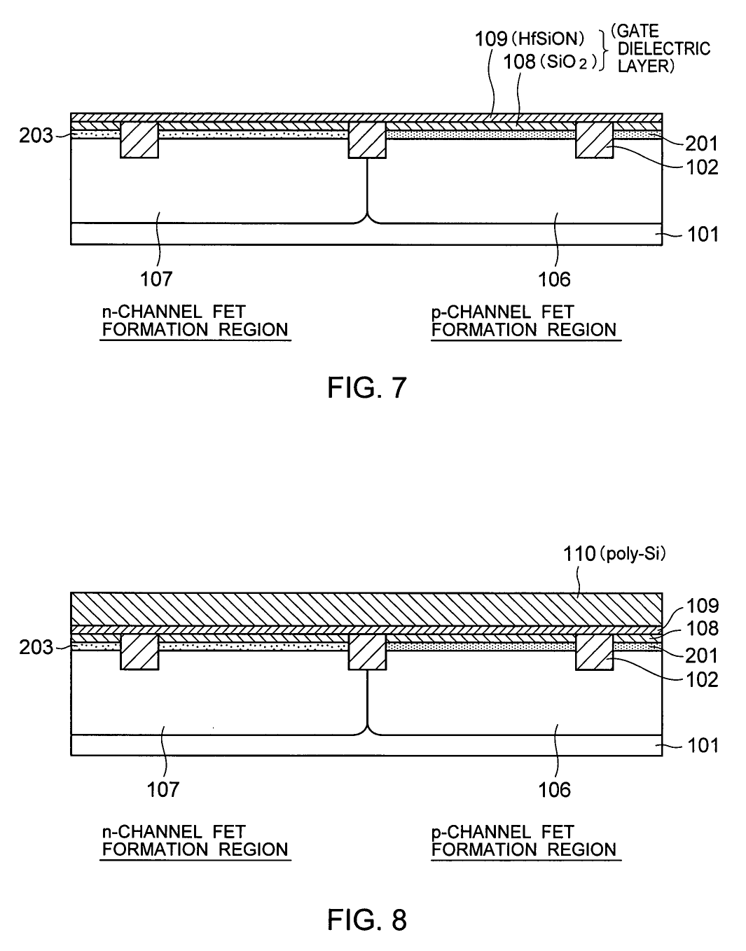

After nitrogen is doped in the HfSiO film in a nitrogen plasma atmosphere or an NH₃ atmosphere, a thermal processing is performed to modify the HfSiO film into a hafnium silicon oxynitride (HfSiON) film 109. Thus, the structure shown in FIG. 7 is obtained. The HfSiON film 109 and the silicon oxide film 108 function as the gate dielectric layer.

Next, as shown in FIG. 8, a polysilicon film 110 is deposited on the HfSiON film 109 as a gate electrode material by CVD (Chemical Vapor Deposition).

Next, a silicon oxide film or a silicon nitride film (hereinafter, “mask material”) 115 is deposited on the polysilicon film 110. Subsequently, patterning is performed on the mask material 115 to form an electrode pattern by photolithography.

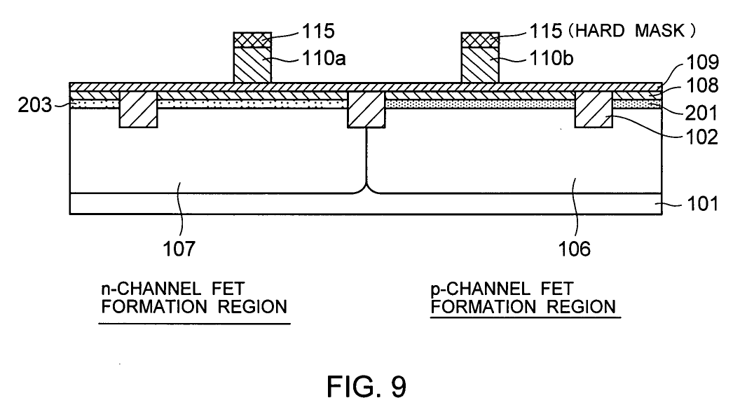

As shown in FIG. 9, the polysilicon film 110 is processed into a gate electrode pattern using the mask material 115 as a hard mask. A gate electrode of the n-channel MISFET obtained as a result is represented by 110a, and a gate electrode of the p-channel MISFET is represented by 110b.

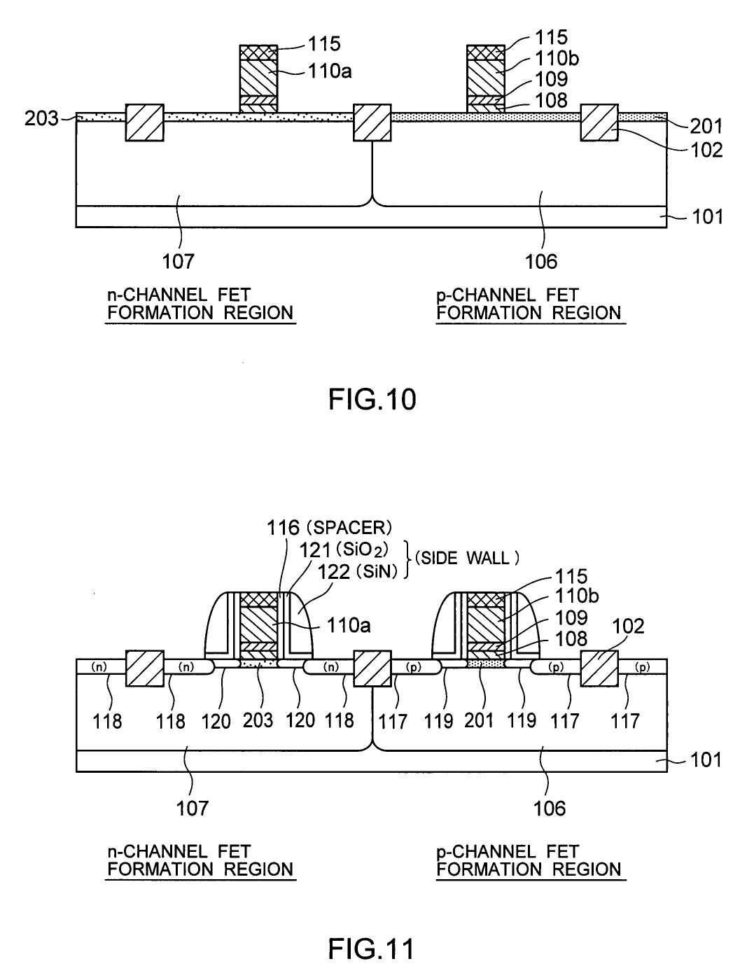

Furthermore, as shown in FIG. 10, the HfSiON film 119 is removed with the dilute hydrofluoric acid solution or the like using the mask material 115 and the gate electrodes 110a and 110b as a mask. At this time, concentration of hydrofluoric acid and etching time are chosen such that the mask material 115 is not completely etched. Specifically, the etching solution and the etching time are appropriately determined based on type and thickness of a high dielectric constant insulation film (HfSiON film 109 in the first embodiment). For example, it is preferable that hydrofluoric acid concentration is 1% or lower, and the etching time is 300 seconds or less. Since the silicon oxide film 108 has very thin thickness of approximately 0.5 nm to 0.8 nm, the silicon oxide film 108 is usually removed at the time of etching of the HfSiON film 109. However, there is no problem even if the silicon oxide film 108 remains on the surface of the silicon substrate 101. The high dielectric constant insulation film is of a material having a dielectric constant higher than that of the silicon oxide film.

Next, side surfaces of the gate electrode materials 110a and 110b and the top surface of the silicon substrate 101 are slightly oxidized. The oxidization process was carried out in an oxygen atmosphere of approximately 0.2% for 5 seconds at a temperature of 1000° C. Film thickness of an oxide film formed by this process was approximately 2 nm. Thereafter, as shown in FIG. 11, offset spacers 116 formed with a silicon oxide film or a silicon nitride film are formed by CVD and RIE. Furthermore, sidewall spacers 121 and 122 formed with a silicon oxide film or a silicon nitride film are formed by CVD and RIE.

Next, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermally processed to activate the impurity, thereby forming a p-type source/drain diffusion layer 117 and an n-type source/drain diffusion layer 118 as shown in FIG. 11.

Subsequently, after sidewalls 121 and 122 are removed, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermal processed to active the impurity, thereby forming a p-type extension region 119 and an n-type extension region 120 as shown in FIG. 11. Halo implantation can be performed subsequently, to suppress the short channel effect.

Next, the sidewalls 121 and 122 are formed again on the sides of the gate electrode materials 110a and 110b by CVD and RIE. While in the first embodiment, a two-layer lamination film of a silicon oxide film and a silicon nitride film is used as the sidewall, a three-layer lamination film formed by accumulating silicon oxide films and/or silicon nitride films can also be used as the sidewall. Further, a single layer film of a silicon nitride film may be used as the sidewall. The structure of the sidewall should be formed according to a device.

While in the first embodiment, the ion implantation of the extension diffusion layer is performed after the ion implantation of the source/drain diffusion layer as described above, the extension diffusion layer can be formed before the formation of the source/drain diffusion layer. In this case, it becomes unnecessary to once remove the sidewalls 121 and 122.

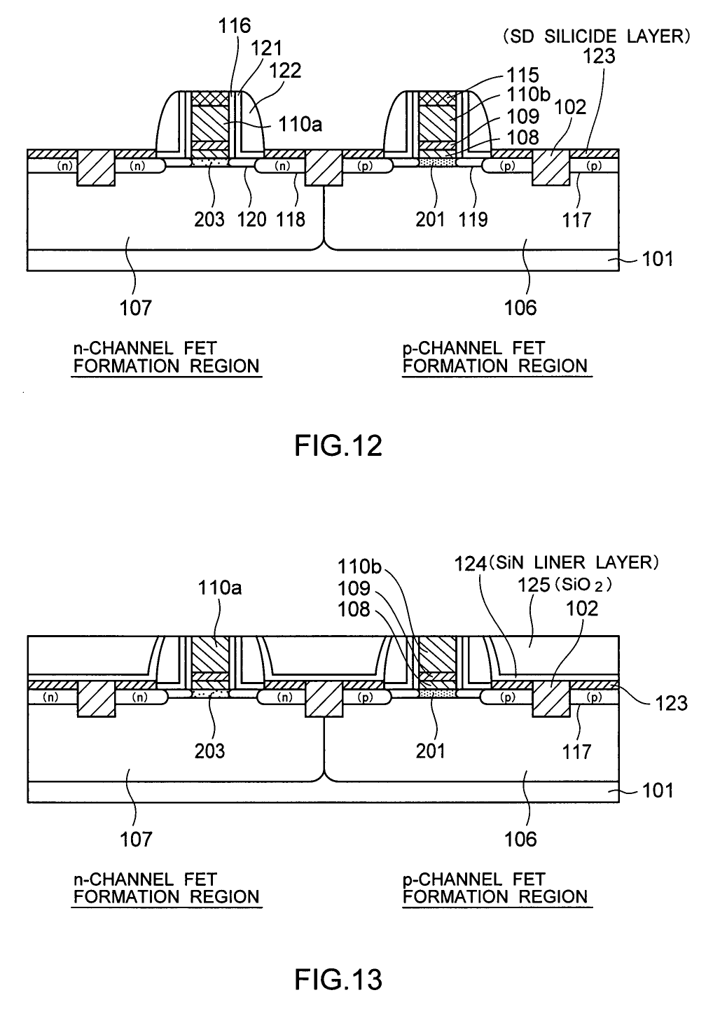

As shown in FIG. 12, a source silicide film/drain silicide film 123 (hereinafter, “SD silicide layer”) is then formed on surfaces of the source/drain diffusion layers 117 and 118 in a self-aligning manner. A material of the SD silicide layer 123 can be, for example, any one of NiPtSix, NiSix (x is a positive number), PtSi (used in the p-channel MISFET region), ErSi (used in the n-channel MISFET region), NiErSi (used in the n-channel MISFET region), or the like.

Next, as shown in FIG. 13, a silicon nitride film 124 is deposited by CVD, and further, a silicon oxide film 125 is deposited thereon. The silicon nitride film 124 functions as an etching stopper. Subsequently, the silicon oxide film 125 is planarized by CMP, dry etching, or wet etching. The silicon oxide film 125, the silicon nitride film 124, and the hard mask 115 are polished to expose top surfaces of the gate electrode 110a and 110b.

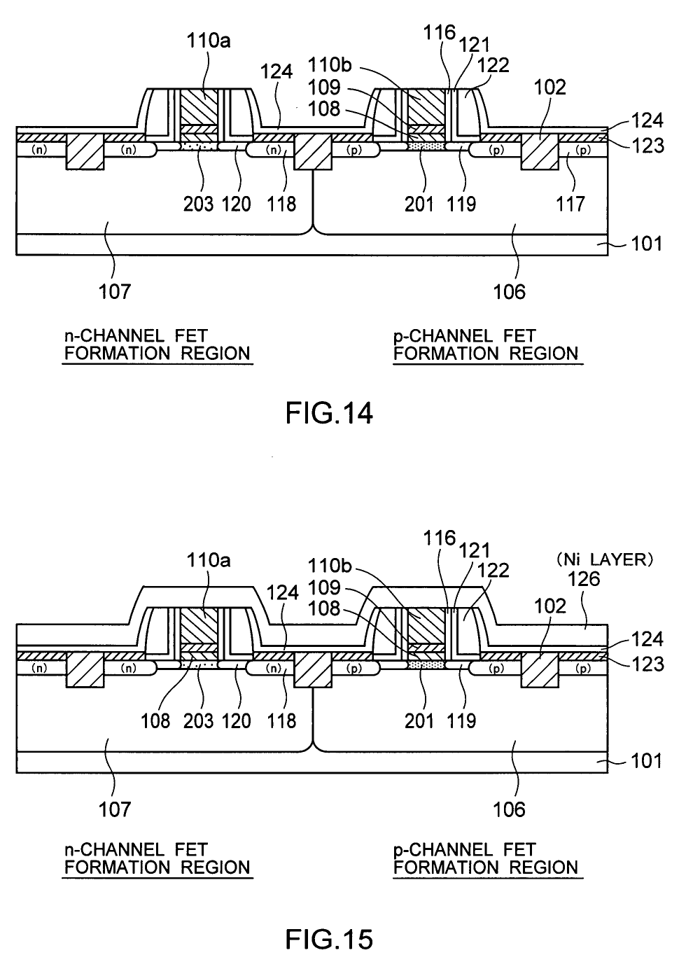

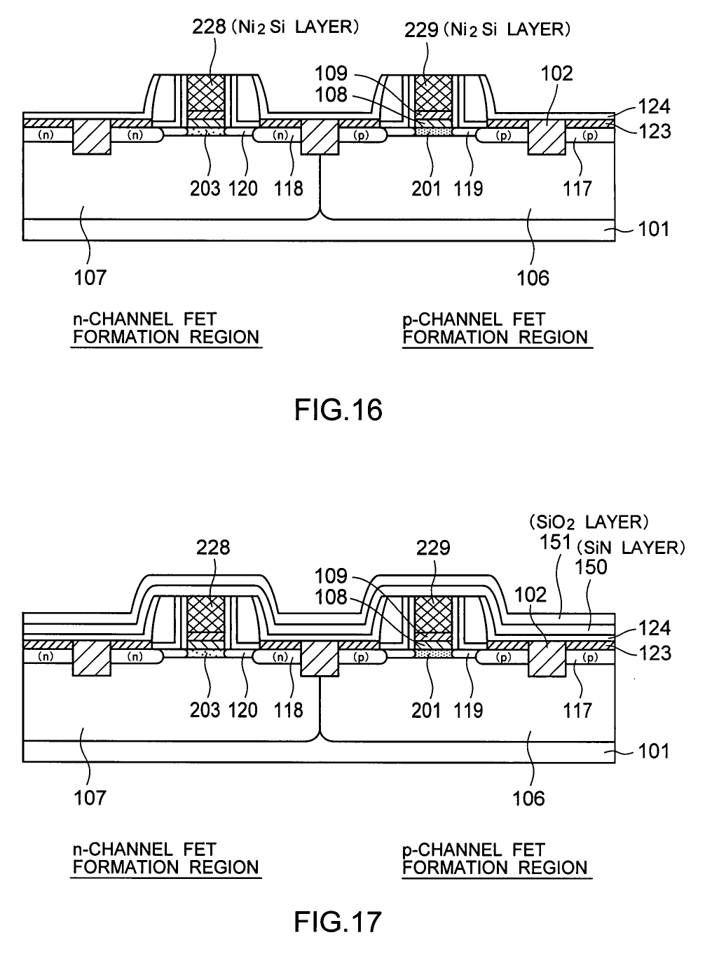

As shown in FIG. 14, the silicon oxide film 125 is then removed. Subsequently, as shown in FIG. 15, a nickel film 126 is deposited. Film thickness of the nickel film 126 is set to be within a range of 1.1 to 1.4 times of a thickness of the gate electrodes 110a and 110b. The nickel film 126 and the gate electrodes 110a and 110b are caused to be reacted at a temperature of 400° C. to 500° C., thereby the gate electrodes 110a and 110b are fully silicided. Thermal processing time in this siliciding process is 30 seconds to 300 seconds assuming that film thickness of the nickel film 126 is 50 nm to 160 nm and a temperature condition is 400° C. to 500° C. More specifically, when the film thickness of the gate electrodes 110a and 110b is approximately 50 nm, required film thickness of the nickel film 126 is 55 nm to 70 nm to fully silicide the gate electrodes 110a and 110b. Such gate electrodes 110a and 110b and the nickel film 126 are thermally processed at a temperature of 400° C. for approximately 60 seconds. Thus, the gate electrodes 110a and 110b become nickel silicide having a composition of Ni₂Si as shown in FIG. 16. Hereinafter, the gate electrodes 110a and 110b are referred to 228 and 229. While the silicon oxide film 125 is removed before formation of Ni₂Si, the silicon oxide film 125 can be removed after the formation of Ni₂Si.

The gate electrode 228 in the n-channel FET region and the gate electrode 229 in the p-channel FET region are both formed of silicide having the composition of Ni₂Si. The gate electrode 229 in the p-channel FET region contains a small amount of boron because of the impurity ion implantation at the time of source/drain formation.

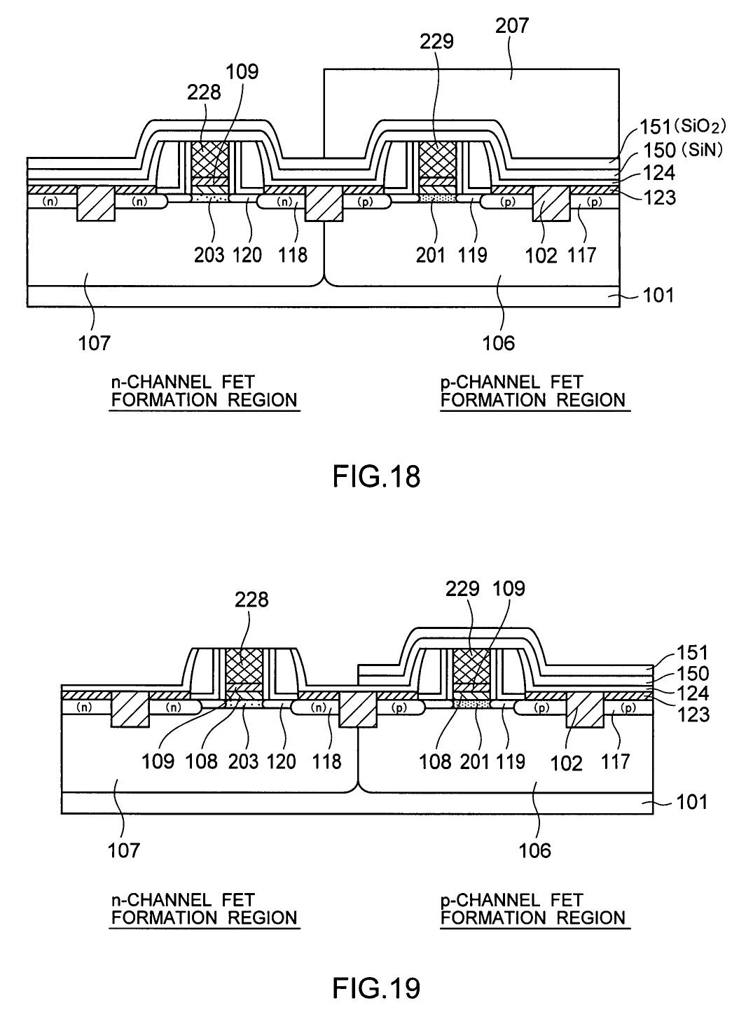

After removing nickel having remained unreacted, as shown in FIG. 17, a silicon nitride film 150 and a silicon oxide film 151 are deposited over the n-channel MISFET region and the p-channel MISFET region. Subsequently, as shown in FIG. 18, the p-channel MISFET region is covered with a photoresist 207. The silicon oxide film 151 on the n-channel MISFET region is either wet etched with a dilute hydrofluoric acid solution or dry etched with a fluorinated gas, using the photoresist 207 as a mask. After the photoresist 207 is removed by ashing, the silicon nitride film 150 is removed by RIE using the remaining silicon oxide film 151 as a mask. Thus, the structure shown in FIG. 19 is obtained. A lamination film composed of the silicon nitride film 150 and the silicon oxide film 151 is used as a mask in a following aluminum segregation process. If a photoresist 152 is removed by a wet processing, a single layer film can be used as a mask instead of the lamination film composed of the silicon nitride film 150 and the silicon oxide film 151.

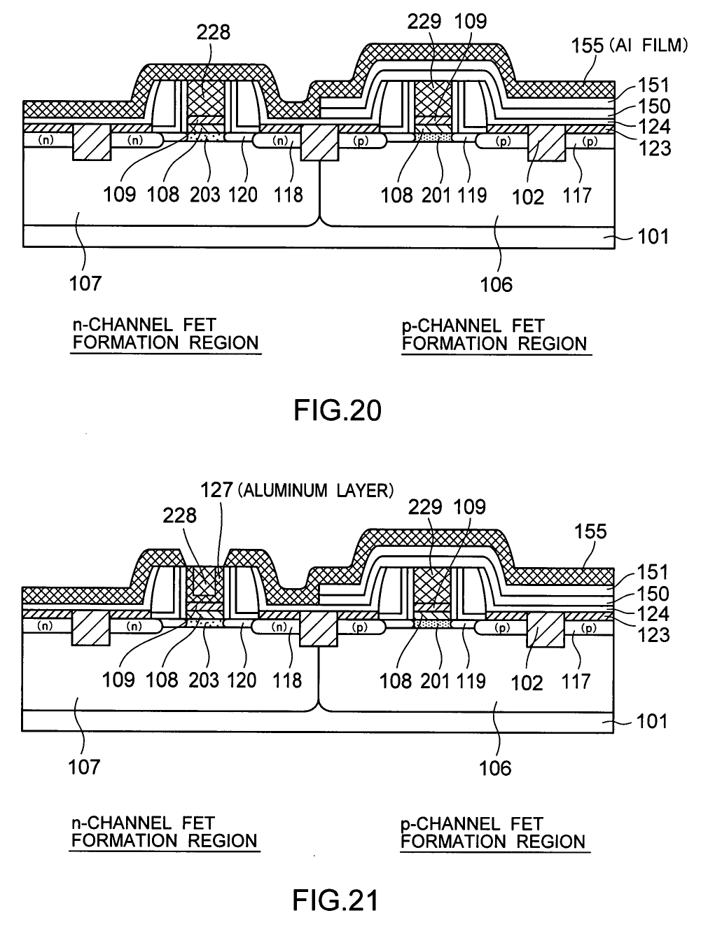

Subsequently, as shown in FIG. 20, an aluminum film 155 is deposited on the n-channel MISFET region and the p-channel MISFET region. Since the p-channel MISFET region is covered with the silicon nitride film 150 and the silicon oxide film 151, the aluminum film 155 does not contact the upper surface of the gate electrode 229. On the other hand, since the top surface of the gate electrode 228 is exposed at the time of depositing aluminum, the aluminum film 155 contacts the upper surface of the gate electrode 228. Film thickness of the aluminum film 155 should be the thickness as explained in the first embodiment, specifically, 5% to 40% of thickness Ta of the gate electrode (silicide) 228.

Next, the structure shown in FIG. 20 is thermally processed at a temperature of 350° C. to 550° C. By this thermal processing, aluminum is segregated to the bottom surface and the side surface of the gate electrode 228. As a result, as shown in FIG. 21, an aluminum layer 127 is formed at the bottom and the side of the gate electrode 228.

The aluminum film 155 remaining on the silicon oxide film 151 and the silicon nitride film 124 is removed by wet etching or dry etching.

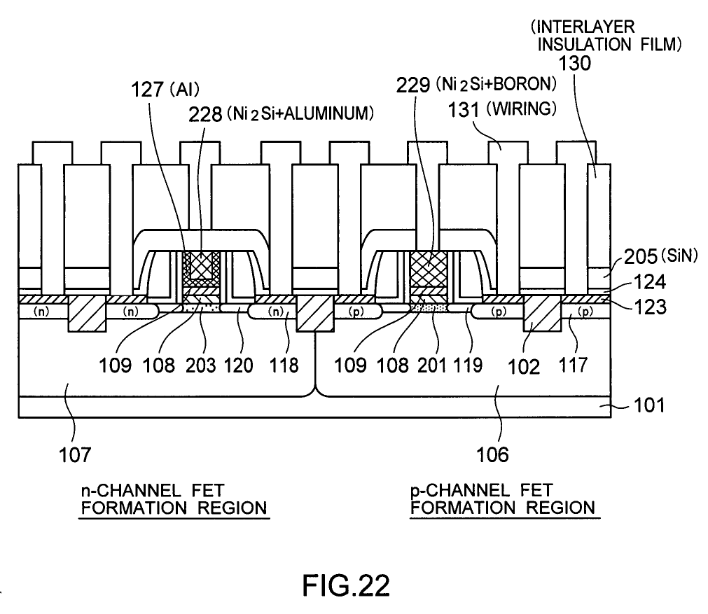

Thereafter, as shown in FIG. 22, by a known method, a silicon nitride liner layer 205 and an inter-layer insulation film 130 are deposited, a contact is formed in the inter-layer insulation film 130, and a wiring 131 and the like are formed.

The silicide forming process of the gate electrode and the aluminum segregation process of the gate electrode can be performed without removing the silicon oxide film 125 shown in FIG. 13 as in a second embodiment of the present invention (explained later). Leaving the silicon oxide film 125, the inter-layer insulation film 130 is deposited, a contact is formed in the inter-layer insulation film 130, and the wiring 131 and the like are formed.

By annealing with a forming gas in a later process, the semiconductor device according to the first embodiment is completed.

The semiconductor device according to the first embodiment includes the silicon substrate 101, the gate dielectric film 108, the gate electrode 128 of the n-channel MISFET, the aluminum layer 127, and the gate electrode 129 of the p-channel MISFET. The gate dielectric film 108 is provided on the silicon substrate 101, and is composed of HfSiO, HfSiON, ZrSiO, ZrSiON, HfZrSiO, or HfZrSiON. The gate electrode 128 of the n-channel MISFET is provided on the gate dielectric film 108, and is composed of nickel silicide NixSiy (x>y) that contains nickel more than silicon. The aluminum layer 127 is provided at the bottom and the side of the gate electrode 128. In other words, the aluminum layer 127 is provided between the bottom surface of the gate electrode 128 and the upper surface of the gate dielectric film 108. The gate electrode 129 of the p-channel MISFET is provided on the gate dielectric film 108, and is composed of nickel silicide NixSiy (x>y) that contains nickel more than silicon.

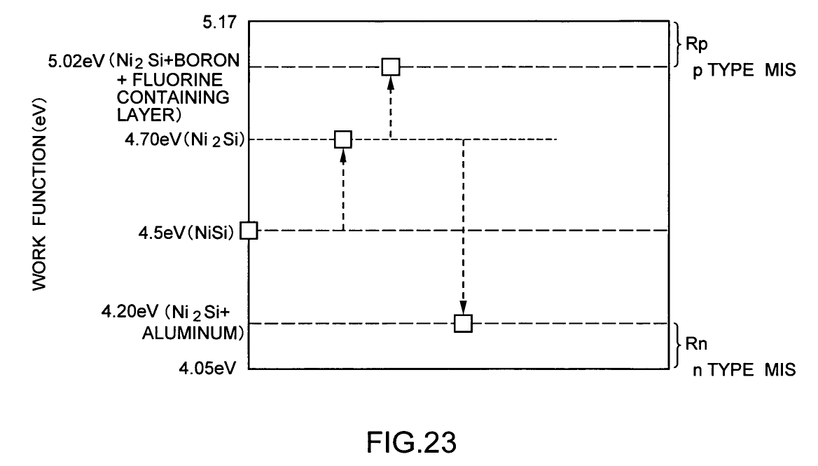

In the first embodiment, the gate electrodes 228 and 229 are composed of Ni₂Si. Further, the nitrogen containing layer 203 is provided at the channel portion of the n-channel MISFET, and the fluorine containing layer 201 is provided at the channel portion of the p-channel MISFET. Effects of the semiconductor device according to the first embodiment are explained with reference to FIG. 23.

FIG. 23 is a graph showing a work function of the gate electrodes of the p-channel MISFET and the n-channel MISFET according to the first embodiment.

When the gate electrode is composed of nickel silicide having a composition of Ni₂Si as in the first embodiment, the work function of the gate electrode is approximately 4.7 eV. Such a work function of approximately 4.7 eV is the work function in the case of Ni₂Si with no impurity implanted.

In the gate electrode of the p-channel FET, the fluorine containing layer 201 is provided under the gate dielectric films 108 and 109. Since the flat band potential is shifted in the positive direction due to the fluorine containing layer 201, the apparent work function of the gate electrode of the p-channel MIS becomes 5.02 eV or higher to be within a range of a region Rp.

The bottom of the gate electrode of the n-channel MIS is the aluminum layer 127. On the aluminum layer 127, nickel silicide containing aluminum and having a composition of Ni₂Si is provided. The work function of the gate electrode having such a structure is 4.20 eV. Furthermore, since the nitrogen containing layer 203 that has a function of shifting the flat band potential in the negative direction is provided in the channel region, the work function of the gate electrode is safely within a range of a region Rn.

Thus, in the first embodiment, Ni₂Si that has the work function higher than NiSi but lower than Ni₃Si or Ni₃₁Si₁₂ is used as the gate electrode. By providing the fluorine containing layer 201 in the channel region of the p-channel FET, the apparent work function of the gate electrode can be shifted to be within the range of the region Rp. In addition, a two-layer structure composed of Ni₂Si and the aluminum layer 127 is used as the gate electrode of the n-channel MIS. This lowers the work function of Ni₂Si to 4.20 eV, and by further providing the nitrogen containing layer 203 in the channel region, the flat band potential corresponding to the work function of 4.2 eV or lower can be obtained. As a result, the threshold voltage of each of the p-channel MIS and the n-channel MIS can be adjusted to an appropriate value.

A fluorine containing channel is formed in the p-channel FET, and a nitrogen containing channel is formed in the n-channel FET. A shift amount of the flat band potential has a correlation such that the shift amount increases as a dose amount of the ion implantation increases. Particularly, a shift amount of the apparent work function of nickel-rich silicide when the fluorine containing channel is used is several times larger than a shift amount when boron is doped in nickel-rich silicide.

A shift amount of the flat band potential is affected by the ion implantation for the adjustment of the threshold voltage and the ion implantation of fluorine or nitrogen. For example, the total shift amount of the flat band potential is the sum of an amount of shift due to counter ion implantation to adjust the threshold voltage and an amount of shift due to the implantation of fluorine and nitrogen.

In the p-channel FET, fluorine concentration reaches the peak at the inter-surface between the channel and the gate dielectric film so that the mobility of the p-channel FET becomes high. Accordingly, its reliability improves.

In the n-channel FET, nitrogen diffuses at the bottom portion of the gate dielectric film. In a normal use of the n-channel FET, a gate electric field is a high electric field of approximately 0.6 MV/cm² or higher. When used in such a high electric field, it is possible to improve the mobility even if nitrogen diffuses at the bottom of the gate dielectric film. As a result, the mobility on a high electric field side is not degraded in both the p-channel FET and the n-channel FET so that high mobility is secured. Therefore, a high drain current can be obtained.

While in the first embodiment, the gate electrode is composed of Ni₂Si, instead of Ni₂Si, Ni₃Si or Ni₃₁Si₁₂ can be used as the gate electrode. Ni₃Si and Ni₃₁Si₁₂ have a higher work function than Ni₂Si. Therefore, in terms of the work function, it is more preferable that the gate electrode is formed with Ni₃Si or Ni₃₁Si₁₂ than Ni₂Si.

However, Ni₂Si contains less nickel than Ni₃Si and Ni₃₁Si₁₂ contain. Therefore, at the time of removing unreacted nickel in the siliciding process, Ni₂Si is less likely to be etched. Furthermore, Ni₂Si has a lower resistivity than Ni₃Si and Ni₃₁Si₁₂. Accordingly, the gate electrode composed of Ni₂Si has a lower resistance than the gate electrode composed of Ni₃Si or Ni₃₁Si₁₂. Moreover, Ni₂Si has a small volume expansion than Ni₃Si and Ni₃₁Si₁₂. Accordingly, the gate electrode composed of Ni₂Si is less likely to be deformed. Thus, considering simplicity of manufacturing, it is more preferable that the gate electrode is formed with Ni₂Si than with Ni₃Si or Ni₃₁Si₁₂.

Normally, modulation of the work function means to shift the flat band potential by modification of the composition of the gate electrode or by modification of the impurity concentration. However, in the first embodiment, the flat band potential is shifted by changing the impurity concentration in the channel region. In this specification, such a shift of the flat band potential caused by modification of the channel region is also included in “modulation of the work function”. Such modulation of the work function is called “apparent modulation of the work function” also.

While in the first embodiment, HfSiON is used as the gate dielectric film, HfSiO can be used as the gate dielectric film instead of HfSiON. Furthermore, by replacing Hf with Zr, ZrSiO or ZrSiON can also be used as the gate dielectric film. Moreover, HfZrSiO or HfZrSiON containing both Hf and Zr can also be used as the gate dielectric film. Such gate dielectric films can further contain Ti, La, or Ta.

HfSiON is superior in thermal resistance to HfSiO. However, by shortening the time of the thermal processing in the manufacturing processes, it becomes possible to use HfSiO as the gate dielectric film.

### Second Embodiment

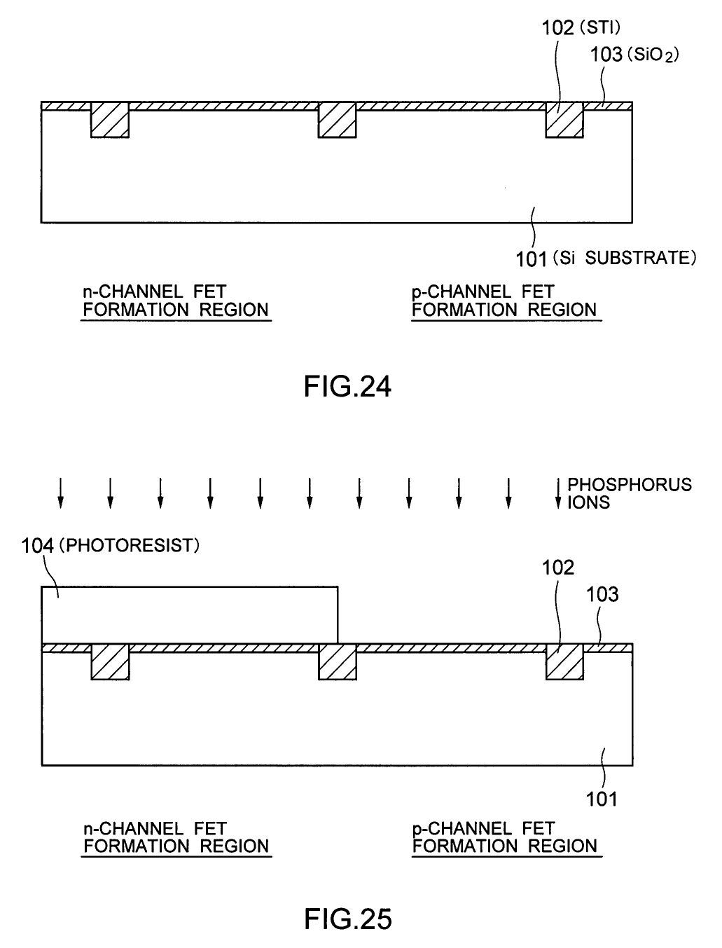

FIGS. 24 to 42 are cross-sections showing a manufacturing method of a semiconductor device according to a second embodiment of the present invention. First, as shown in FIG. 24, trenches are formed in the silicon substrate 101, and by filling the trenches with silicon oxide film, the STIs 102 are formed. The sacrificial oxide film 103 is formed on a surface of the silicon substrate 101.

Next, as shown in FIG. 25, the n-channel MISFET formation region is covered with the photoresist 104. To form the n-type well, an n-type impurity (for example, phosphorus) is ion-implanted in the p-channel MISFET formation region. Implantation of phosphorus is also carried out for the purpose of adjustment of the threshold voltage of a transistor besides formation of an impurity diffusion layer. For fine adjustment of the threshold voltage of a transistor, boron ion or indium ion is implanted in some cases. As in the first embodiment, fluorine ion can be implanted in the p-channel MISFET formation region using the photoresist 104 as a mask.

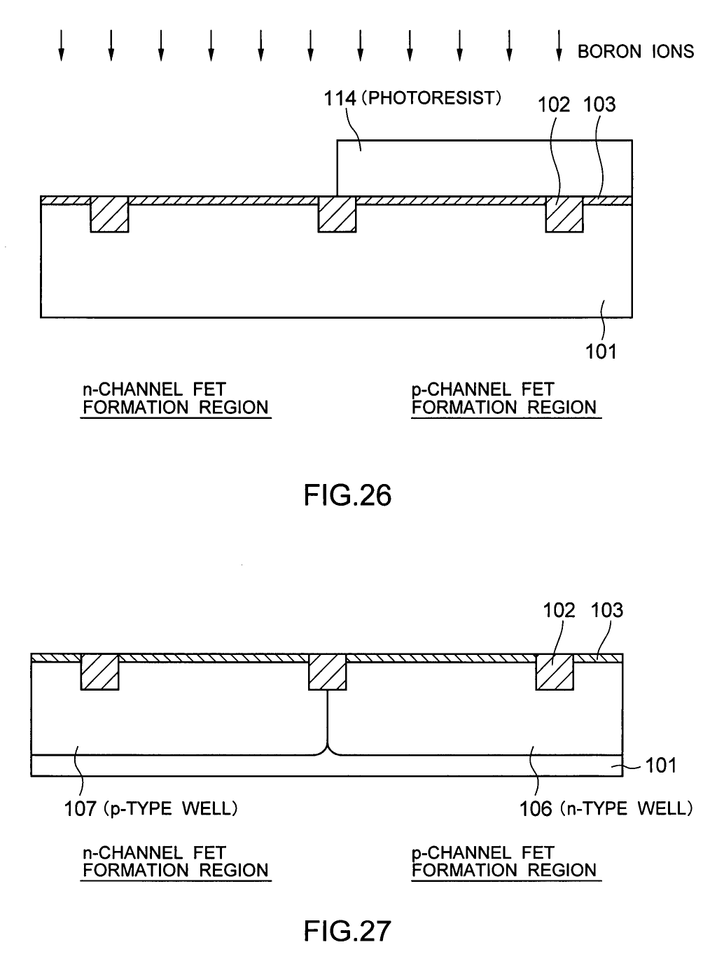

After removing the photoresist 104, as shown in FIG. 26, the p-channel MISFET formation region is covered with a photoresist 114. Subsequently, to form a p-type well, a p-type impurity (for example, boron) is ion-implanted in the n-channel MISFET formation region. Implantation of boron is also carried out for the purpose of adjustment of the threshold voltage of a transistor besides formation of an impurity diffusion layer. For fine adjustment of the threshold voltage of a transistor, arsenic ion or phosphorus ion is implanted in some cases. As in the first embodiment, nitrogen ion can be implanted in the n-channel MISFET using the photoresist 114 as a mask.

After removing the photoresist 114, by thermal diffusion of these impurities, the n-type well 106 and the p-type well 107 are formed as shown in FIG. 27. In the second embodiment, the fluorine containing layer 201 and the nitrogen containing layer 203 can be formed at surface portions of the n-type well 106 and the p-type well 107, respectively, as in the first embodiment. The fluorine containing layer 201 has a function of shifting the flat band potential in the positive direction and the nitrogen containing layer 203 has a function of shifting the flat band potential in the negative direction. If it is not required to set the threshold voltage lower, the fluorine containing layer 201 and the nitrogen containing layer 203 are not required.

The sacrificial oxide film 103 is removed using an NH₄F solution. Immediately after cleaning the surface with a dilute hydrofluoric acid solution of 0.5% to 5%, the silicon oxide film 108 of approximately 0.5 nm to 0.8 nm is formed in an oxygen atmosphere. Furthermore, a hafnium silicon oxide film (HfSiO film) having a film thickness of approximately 2.0 nm is formed on the silicon substrate 101 using tetrakisdiethylaminohafnium, diethylsilane, and oxygen.

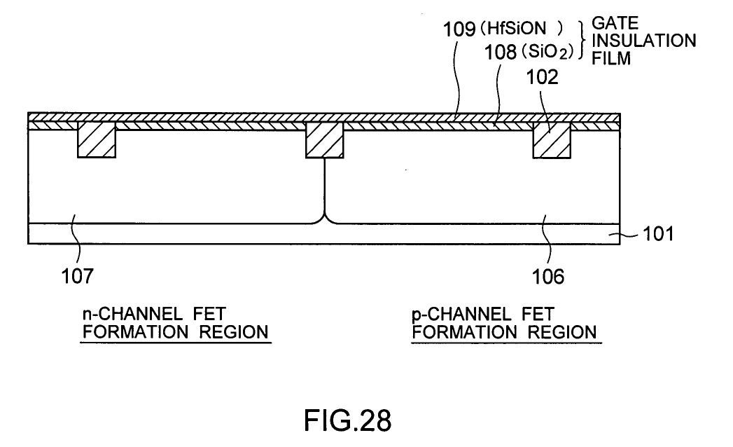

After nitrogen is doped in the HfSiO film in a nitrogen plasma atmosphere or an NH₃ atmosphere, a thermal processing is performed to modify the HfSiO film into the hafnium silicon oxynitride (HfSiON) film 109. Thus, the structure shown in FIG. 28 is obtained. The HfSiON film 109 and the silicon oxide film 108 function as the gate dielectric layer.

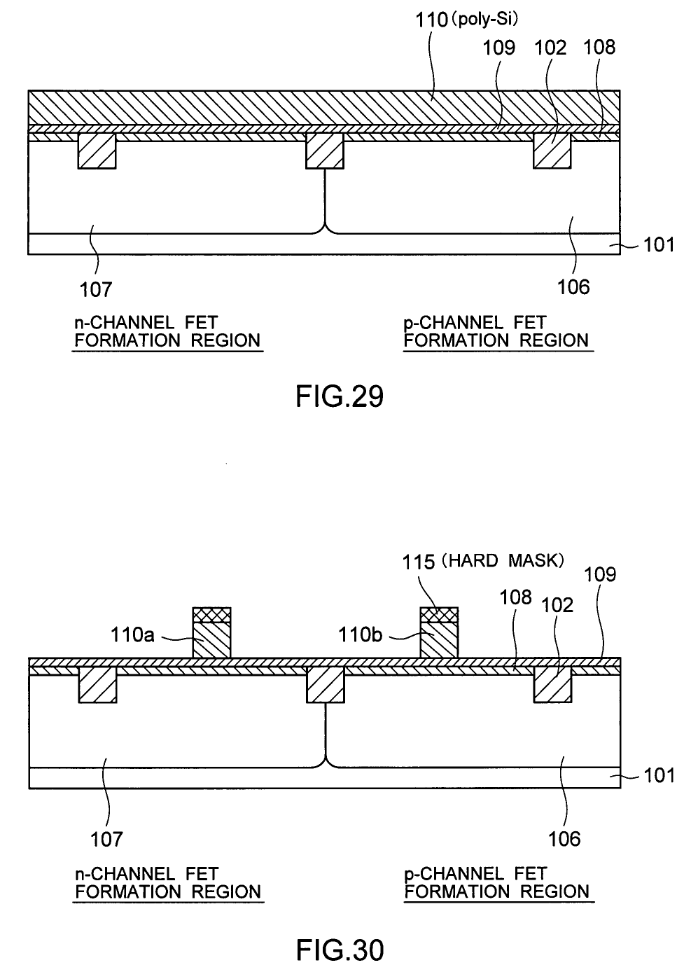

Next, as shown in FIG. 29, the polysilicon film 110 is deposited on the HfSiON film 109 as a gate electrode material by CVD.

Next, a silicon oxide film, a silicon nitride film, or a lamination film of these materials (hereinafter, “mask material”) 115 is deposited on the polysilicon film 110. Subsequently, patterning is performed on the mask material 115 to form an electrode pattern by photolithography.

As shown in FIG. 30, the polysilicon film 110 is processed into a gate electrode pattern using the mask material 115 as a hard mask. The gate electrode of the n-channel MISFET obtained as a result is represented by 110a, and the gate electrode of the p-channel MISFET is represented by 110b.

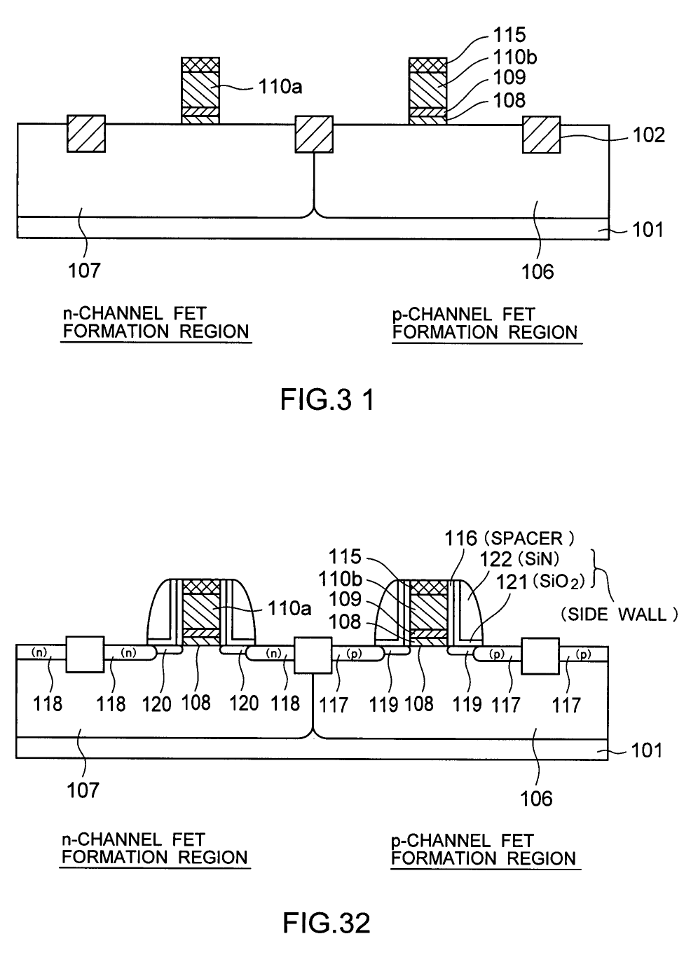

Furthermore, as shown in FIG. 31, the HfSiON film 109 is removed with the dilute hydrofluoric acid solution or the like using the mask material 115 and the gate electrodes 110a and 110b as a mask. At this time, concentration of hydrofluoric acid and etching time are determined such that the mask material 115 is not completely etched. Specifically, the etching solution and the etching time are appropriately determined based on material and thickness of a high dielectric constant insulation film (HfSiON film 109 in the second embodiment). For example, it is preferable that hydrofluoric acid concentration is 1% or lower, and the etching time is 300 seconds or less. Since the silicon oxide film 108 has very thin thickness of approximately 0.5 nm to 0.8 nm, the silicon oxide film 108 is usually removed at the time of etching of the HfSiON film 109. However, there is no problem even if the silicon oxide film 108 remains on the surface of the silicon substrate 101. The high dielectric constant insulation film is of a material having a relative permittivity higher than that of the silicon oxide film.

Next, sides of the gate electrode materials 110a and 110b and the surface of the silicon substrate 101 are slightly oxidized. The oxidization process was carried out in an oxygen atmosphere of approximately 0.2% for 5 seconds at a temperature of 1000° C. Film thickness of an oxide film formed by this process was approximately 2 nm. Thereafter, as shown in FIG. 32, the offset spacers 116 are formed by CVD and RIE.

Next, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermally processed to activate the impurity, thereby forming the p-type extension region 119 and the n-type extension region 120 as shown in FIG. 32. Subsequently, hollow implantation can be performed to suppress the short channel effect.

Furthermore, the sidewall spacers 121 and 122 formed with a silicon oxide film or a silicon nitride film are formed by CVD and RIE.

Next, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermally processed to activate the impurity, thereby forming the p-type source/drain diffusion layer 117 and the n-type source/drain diffusion layer 118 as shown in FIG. 32.

While in the second embodiment, a two-layer lamination film of a silicon oxide film and a silicon nitride film is used as the sidewall, a three-layer lamination film formed by laminating silicon oxide films and/or silicon nitride films can also be used as the sidewall. The structure of the sidewall should be formed according to a device.

While in the second embodiment, the ion implantation of the extension diffusion layer is performed before the ion implantation of the source/drain diffusion layer as described above, the extension diffusion layer can be formed after the formation of the source/drain diffusion layer. In this case, it becomes necessary to once remove the sidewalls 121 and 122.

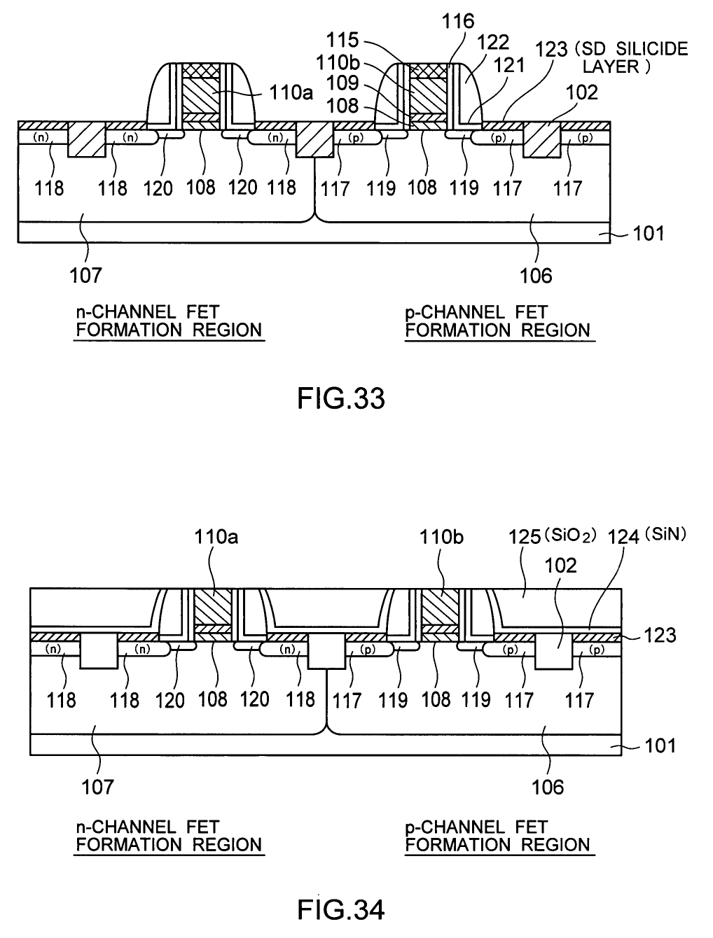

As shown in FIG. 33, the source silicide film/drain silicide film 123 (hereinafter, “SD silicide layer”) is then formed on surfaces of the source/drain diffusion layers 117 and 118 in a self-aligning manner. A material of the SD silicide layer 123 can be, for example, any one of NiPtSix, NiSix, PtSi (used in the p-channel MISFET region), ErSi (used in the n-channel MISFET region), NiErSi (used in the n-channel MISFET region), or the like.

Next, as shown in FIG. 34, the silicon nitride film 124 is deposited by CVD, and further, the silicon oxide film 125 is deposited thereover. The silicon nitride film 124 functions as an etching stopper. Subsequently, the silicon oxide film 125 is planarized by CMP (Chemical Mechanical Polishing), dry etching, or wet etching. The silicon oxide film 125, the silicon nitride film 124, and the hard mask 115 are polished to expose top surfaces of the gate electrodes 110a and 110b.

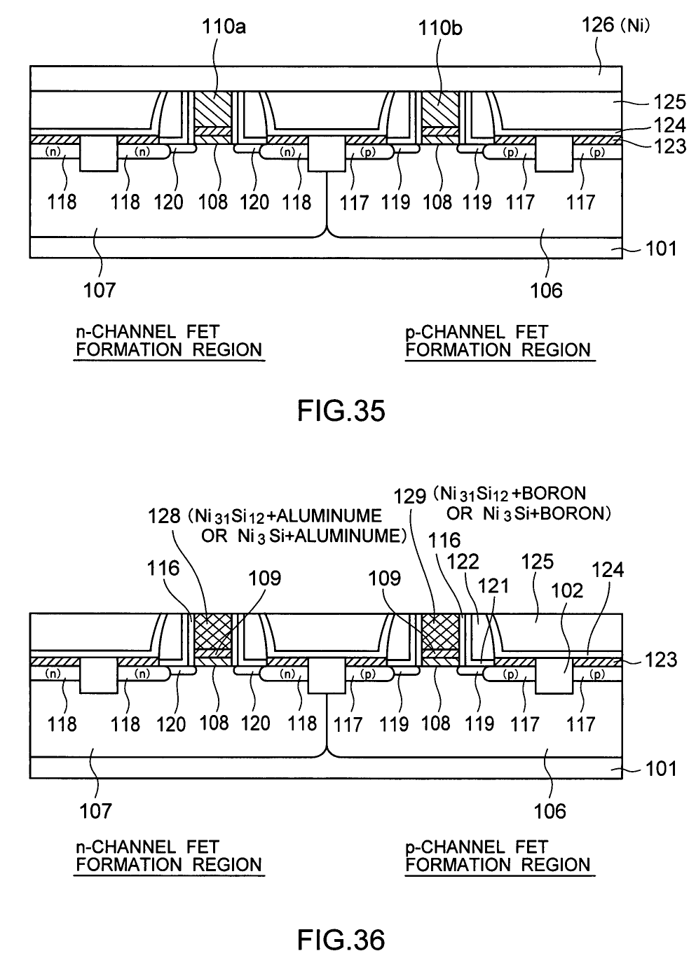

Subsequently, as shown in FIG. 35, the nickel film 126 is deposited. Film thickness of the nickel film 126 is 1.65 times as thick as thickness of the gate electrodes 110a and 110b or thicker. The nickel film 126 and the gate electrodes 110a and 110b are caused to be reacted at a temperature of 400° C. to 500° C., thereby fully siliciding the gate electrodes 110a and 110b to be full silicide electrodes. Thermal processing time in this siliciding process is 30 seconds to 300 seconds assuming that film thickness of the nickel film 126 is 50 nm to 160 nm and a temperature condition is 400° C. to 500° C. More specifically, when the film thickness of the gate electrodes 110a and 110b is approximately 50 nm, required film thickness of the nickel film 126 is 82.5 nm or thicker to fully silicide the gate electrodes 110a and 110b to have a composition of Ni₃Si. Such gate electrodes 110a and 110b and the nickel film 126 are thermally processed at a temperature of 400° C. for approximately 260 seconds. Thus, the gate electrodes 110a and 110b become nickel silicide having the composition of Ni₃Si or Ni₃₁Si₁₂. As a result, the structure shown in FIG. 36 is obtained.

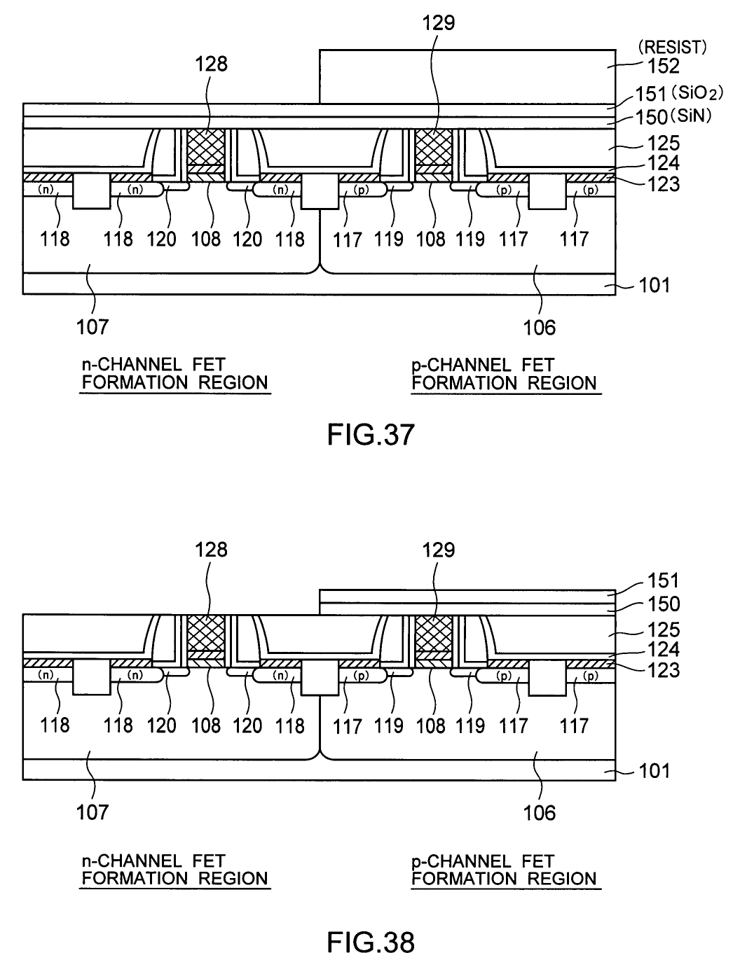

Next, as shown in FIG. 37, the silicon nitride film 150 and the silicon oxide film 151 are deposited over the n-channel MISFET region and the p-channel MISFET region. The photoresist 152 is formed so as to cover the p-channel MISFET region. The silicon oxide film 151 is etched by either wet etching with a dilute hydrofluoric acid solution or by dry etching with a fluorinated gas, using the photoresist 152 as a mask. After the photoresist 152 is removed by ashing, the silicon nitride film 150 is removed by RIE using the remaining silicon oxide film 151 as a mask. Thus, the structure shown in FIG. 38 is obtained. A lamination film composed of the silicon nitride film 150 and the silicon oxide film 151 is used as a mask in a following aluminum segregation process. If the photoresist 152 is removed by a wet processing, a single layer film can be used as a mask instead of the layered film composed of the silicon nitride film 150 and the silicon oxide film 151.

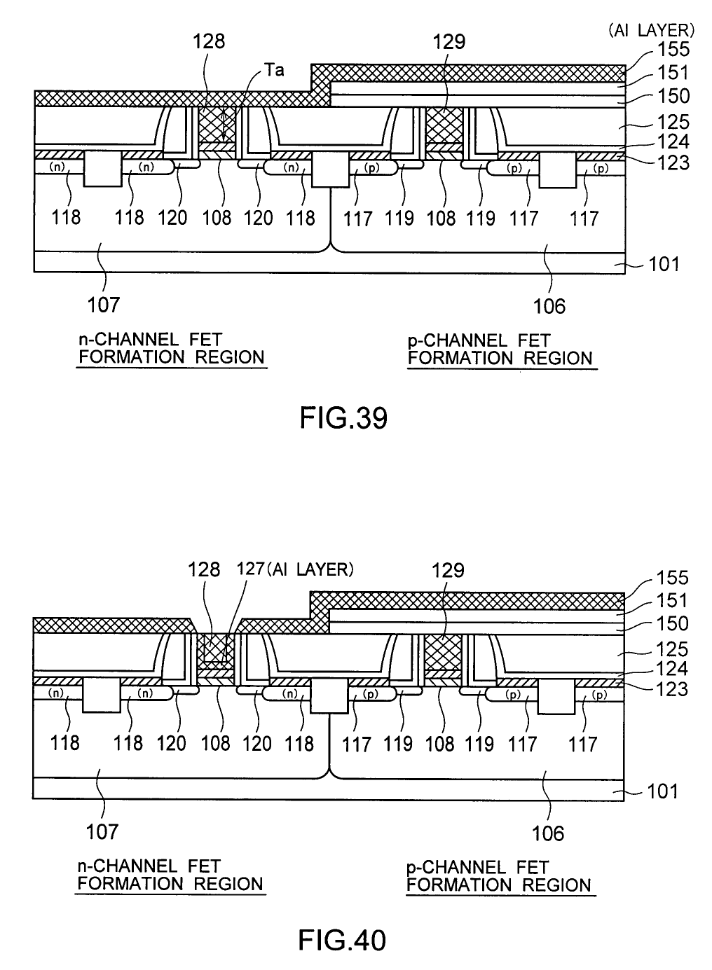

Subsequently, as shown in FIG. 39, the aluminum film 155 is deposited over the n-channel MISFET region and the p-channel MISFET region. Since the p-channel MISFET region is covered with the silicon nitride film 150 and the silicon oxide film 151, the aluminum film 155 does not contact the upper surface of the gate electrode 129. On the other hand, since the top surface of the gate electrode 128 is exposed, the aluminum film 155 contacts the upper surface of the gate electrode 128.

Film thickness of the aluminum film 155 is 5% to 40% of thickness Ta of the gate electrode (silicide) 128. For example, if thickness Ta of the gate electrode 128 is 100 nm, the film thickness of the aluminum film 155 is 5 nm to 40 nm. The film thickness of the aluminum film 155 can be thicker than 40% of thickness Ta. However, after a thermal processing to be described later, the aluminum film 155 remaining on the silicon nitride film 151 and the silicon oxide film 125 is required to be removed. If the film thickness of the aluminum film 155 is more than 40% of thickness Ta, it takes long time for a removing process of this aluminum film 155. If the film thickness of the aluminum film 155 is less than 5% of thickness Ta, an aluminum layer is not to be segregated at the bottom of the gate electrode 128. Considering the above aspects, it is found that the film thickness of the aluminum film 155 is preferable to be 5% to 40% of thickness Ta of the gate electrode (silicide) 128.

Next, the structure shown in FIG. 39 is thermally processed at a temperature of 350° C. to 550° C. By this thermal processing, aluminum is segregated to the bottom surface and the side surface of the gate electrode 128. As a result, as shown in FIG. 40, the aluminum layer 127 is formed on the bottom and the sides of the gate electrode 128. At this time, if a thermal processing temperature is too high, agglomeration is caused in a silicide film 123 on the source/drain layers 117 and 118. If this thermal processing temperature is too low, the aluminum layer is not segregated to the bottom of the gate electrode 128. Considering the above aspects, it is found that the thermal processing temperature is preferable to be 350° C. to 550° C.

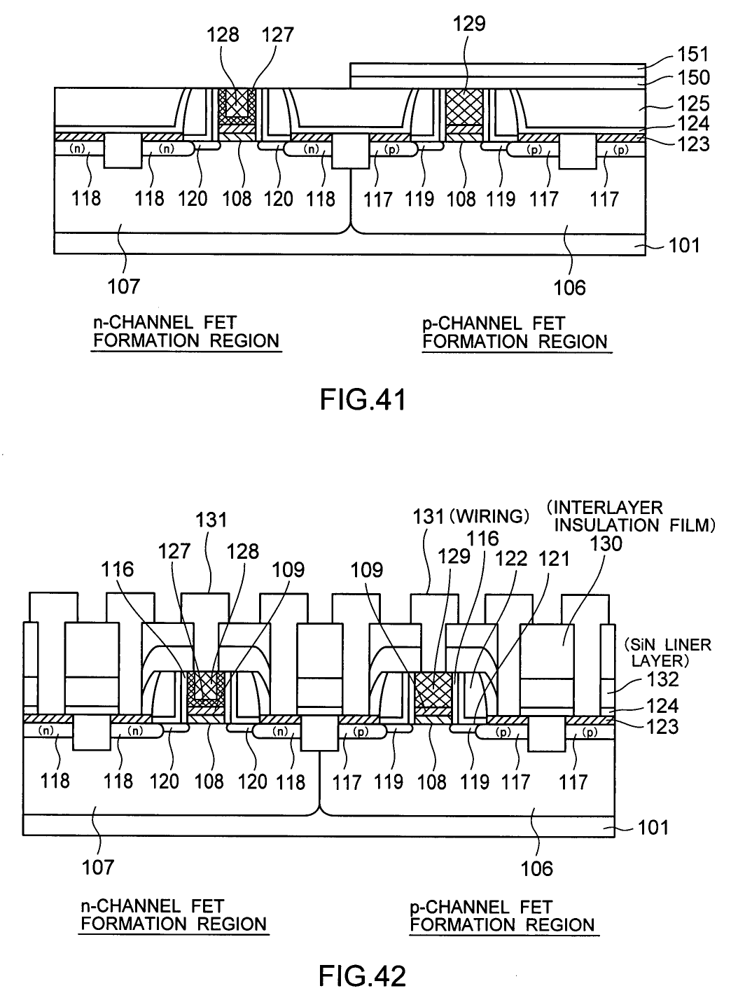

The aluminum film 155 remaining on the silicon oxide film 151 and the silicon oxide film 125 is removed by wet etching or dry etching. Thus, the structure shown in FIG. 41 is obtained.

After removing the silicon oxide 125, as shown in FIG. 42, by a known method, the SiN liner layer 132 and the inter-layer insulation film 130 are deposited, a contact is formed in the inter-layer insulation film 130, and the wiring 131 and the like are formed.

The inter-layer insulation film 130 can be deposited, a contact can be formed in the inter-layer insulation film 130, and the wiring 131 and the like can be formed without removing the silicon oxide film 125. Furthermore, the silicide formation process of the gate electrode and the aluminum segregation process of the gate electrode can be performed after removing the silicon oxide film 125 as in the second embodiment.

By annealing with a forming gas in a later process, the semiconductor device according to the second embodiment is completed.

In the second embodiment, the gate electrodes 128 and 129 are composed of Ni₃Si or Ni₃₁Si₁₂.

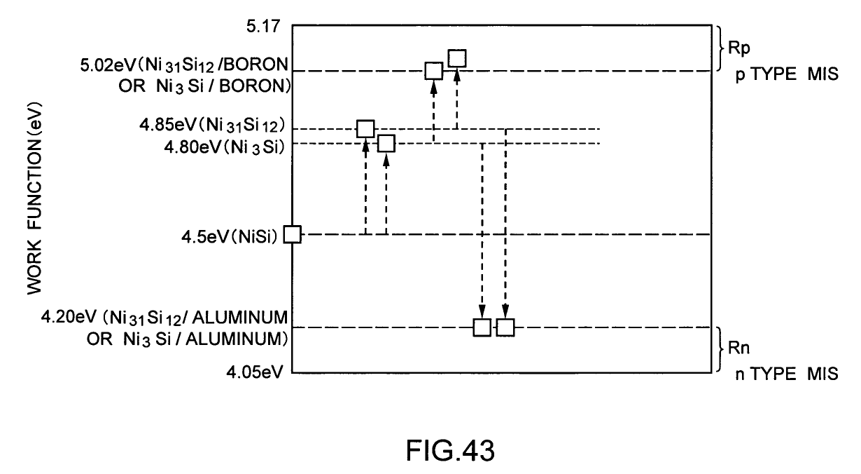

With reference to FIG. 43, effects of the semiconductor device according to the second embodiment are explained.

FIG. 43 is a graph showing a work function of the gate electrodes of the p-channel MISFET and the n-channel MISFET according to the second embodiment. In the second embodiment, an HfSiO film is used as the gate electrode. Generally, for the p-channel MIS, the work function of the gate electrode is preferable to be 5.02 eV or higher (the region Rp in FIG. 43). For the n-channel MIS, the work function of the gate electrode is preferable to be 4.20 eV or lower (the region Rn in FIG. 43). With such work functions, it becomes possible to adjust the threshold voltage of each of the n-channel MIS and the p-channel MIS to an appropriate value.

When the gate electrode is composed of nickel silicide having a composition of NiSi, the work function of the gate electrode is approximately 4.5 eV. Such a work function of approximately 4.5 eV is the work function in the case of NiSi without implantation of an impurity. Conventionally, to make this work function approach the region Rp or the region Rn, ion implantation of an impurity in NiSi has been performed. For example, for the gate electrode of the n-channel MIS, ion implantation of phosphorus or arsenic, and for the gate electrode of the p-channel MIS, ion implantation of boron or boron fluoride have been performed. By this conventional method, the gate electrode of the n-channel MIS is lowered to approximately 4.4 eV, and the work function of the gate electrode of the p-channel MIS is raised to approximately 4.7 eV. However, a preferable work function has not been able to be obtained for both.

In contrast, when the gate electrode is composed of nickel silicide having a composition of Ni₃Si or Ni₃₁Si₁₂ as in the second embodiment, the work function of the gate electrode is approximately 4.8 eV or approximately 4.85 eV. Such a work function of approximately 4.8 eV or approximately 4.85 eV is the work function in the case of Ni₃Si or Ni₃₁Si₁₂ with no impurity implanted. When fluorine is ion-implanted in the channel portion of the gate electrode having the composition of Ni₃Si or Ni₃₁Si₁₂, the apparent work function of the gate electrode of the p-channel MIS becomes 5.02 eV or higher, to be within a range of the region Rp.

The bottom of the gate electrode of the n-channel MIS is the aluminum layer 127. Nickel silicide containing aluminum and having a composition of Ni₃Si or Ni₃₁Si₁₂ is provided on the aluminum layer 127. The work function of the gate electrode having such a structure is only dependent on the aluminum layer and independent of a composition of nickel silicide on the aluminum layer, and becomes 4.20 eV. Therefore, by adjusting impurity concentration in the channel portion, the work function of the gate electrode can be easily brought to be within a range of the region Rn.

Thus, in the second embodiment, Ni₃Si or Ni₃₁Si₁₂ that has the work function higher than NiSi is used as the gate electrode. Therefore, the apparent work function of the gate electrode of the p-channel MIS can be shifted to be within the range of the region Rp by ion implantation of fluorine into the channel portion. In addition, a two-layer lamination structure composed of Ni₃Si or Ni₃₁Si₁₂ and the aluminum layer 127 is used as the gate electrode of the n-channel MIS. This lowers the apparent work function of Ni₃Si or Ni₃₁Si₁₂ (4.80 eV or 4.85 eV) to 4.20 eV. As a result, the threshold voltage of each of the p-channel MIS and the n-channel MIS can be adjusted to an appropriate value.

In the second embodiment, the aluminum layer 127 is formed at the bottom of the gate electrode 101a by utilizing the deposited aluminum film 155. Accordingly, aluminum does not diffuse in the silicon oxide film 125 used as the inter-layer insulation film. Therefore, the reliability of the entire semiconductor device is not deteriorated.

While in the second embodiment, HfSiON is used as the gate dielectric film, HfSiO can be used as the gate dielectric film instead of HfSiON. Furthermore, by replacing Hf with Zr, ZrSiO or ZrSiON can also be used as the gate dielectric film. Moreover, HfZrSiO or HfZrSiON containing both Hf and Zr can also be used as the gate dielectric film. Such gate dielectric films can further contain Ti, La, or Ta.

HfSiON is superior in thermal resistance to HfSiO. However, by shortening the time of the thermal processing in the manufacturing processes, it becomes possible to use HfSiO as the gate dielectric film.

### Third Embodiment

In a third embodiment of the present invention, the SD silicide layer 123 is composed of NiSi (nickel monosilicide) containing platinum. NiSi containing platinum is formed, for example, as follows. First, an NiPt film containing platinum (Pt) for 5% or more is formed on the structure shown in FIG. 11. Subsequently, annealing is performed thereon at a temperature of 350° C. or higher. This causes NiPt on the source/drain layers 117 and 118 to react with silicon to be silicided. NiPt on the sidewall film 122, NiPt on the STI 102, and NiPt on the hard mask 115 are not silicided. Next, NiPt remaining unreacted on the sidewall film 122, the STI 102, and the hard mask 115 is removed using a compound liquid of nitric acid and hydrochloric acid (so called aqua regia). By performing annealing again at a temperature of 500° C. or lower, the SD silicide layer 123 containing platinum and having the composition of NiSi is formed. Thereafter, the processes explained with reference to the figures of FIG. 12 and following processes are performed, and the semiconductor device is completed.

When the SD silicide layer 123 is a regular silicide (NiSi, etc.) not containing Pt, in a heating process at a temperature of 500° C. or higher, agglomeration can be caused in the SD silicide layer 123. This leads to a failure such as junction leakage.

In contrast, according to the third embodiment, since the SD silicide layer 123 contains Pt, agglomeration is not caused. Therefore, a failure such as junction leakage does not occur in the semiconductor device according to the third embodiment. As described above, by applying the third embodiment to the first embodiment, similar effects to the first embodiment can be achieved in the third embodiment. In this case, the fluorine containing layer and the nitrogen containing layer are to be formed at the surfaces of the p-type well and the n-type well in the third embodiment.

The third embodiment can also be applied to the second embodiment. In this case, although the fluorine containing layer and the nitrogen containing layer are not provided, the effects of the second embodiment can be achieved in the third embodiment.

In the third embodiment, the SD silicide layer 123 and the silicide layers 128 (or 228) and 129 on the gate electrode can be formed by annealing in two steps.

The impurity can be doped either before processing or after processing the gate electrode. While polysilicon is used as the material of the gate electrode, the material of the gate electrode can be amorphous silicon.

As for the semiconductor substrate, an SOI substrate (Silicon On Insulator) can be used besides a silicon substrate. A plane orientation of the semiconductor substrate is not specifically limited. The third embodiment can also be applied to a Fin-type FET besides a planar transistor.

While in the third embodiment, HfSiON is used as the gate dielectric film, HfSiO can be used as the gate dielectric film instead of HfSiON. Furthermore, by replacing Hf with Zr, ZrSiO or ZrSiON can also be used as the gate dielectric film. Moreover, HfZrSiO or HfZrSiON containing both Hf and Zr can also be used as the gate dielectric film. Such gate dielectric films can further contain Ti, La, or Ta.

HfSiON is superior in thermal resistance to HfSiO. However, by shortening the time of the thermal processing in the manufacturing processes, it becomes possible to use HfSiO as the gate dielectric film.

### Fourth Embodiment

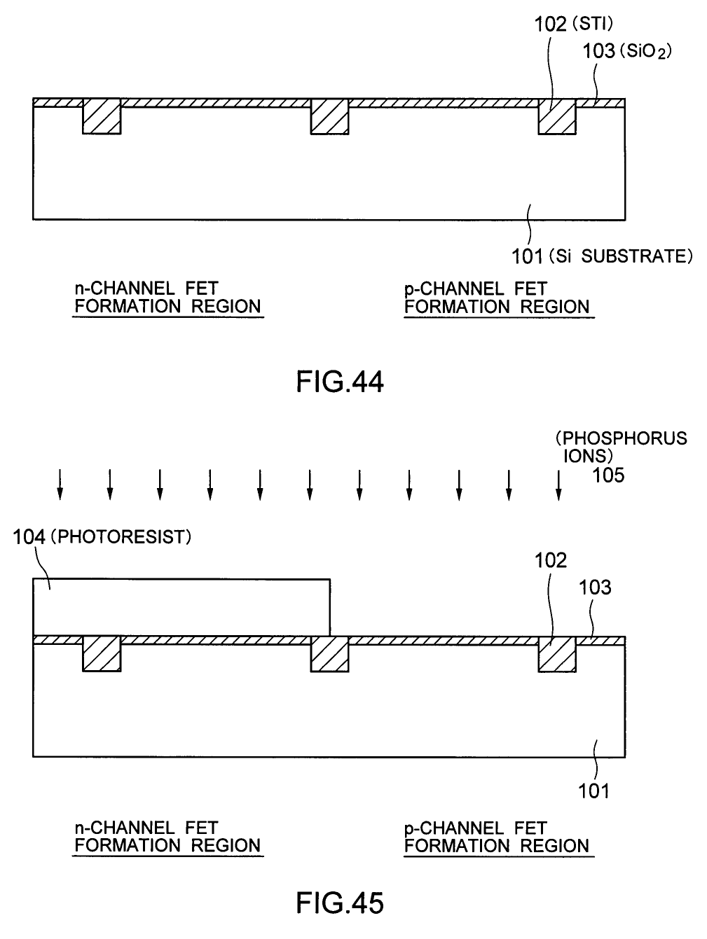

FIGS. 44 to 58 are cross-sections showing a manufacturing method of a semiconductor device according to a fourth embodiment of the present invention. First, as shown in FIG. 44, trenches are formed in the silicon substrate 101, and by filling the trenches with silicon oxide film, the STIs 102 are formed. The sacrificial oxide film 103 is formed on the surface of the silicon substrate 101.

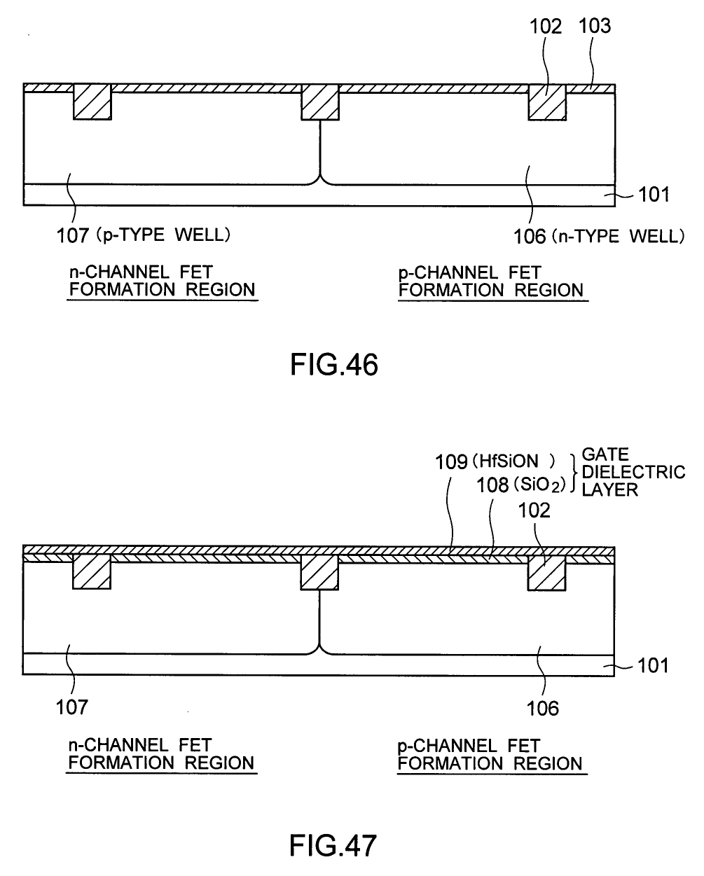

Next, as shown in FIG. 44, the n-channel MISFET formation region is covered with the photoresist 104. To form the n-type well, an n-type impurity (for example, phosphorus) is ion-implanted in the p-channel MISFET formation region. Implantation of phosphorus is also carried out for the purpose of adjustment of the threshold voltage of a transistor besides formation of an impurity diffusion layer. Although not shown, similarly, the p-channel MISFET formation region is covered with a photoresist. To form a p-type well, a p-type impurity (for example, boron) is ion-implanted in the n-channel MISFET formation region. Subsequently, by thermal diffusion of these impurities, the n-type well 106 and the p-type well 107 are formed as shown in FIG. 46.

The sacrificial oxide film 103 is removed using an NH₄F solution. Immediately after cleaning the surface with a dilute hydrofluoric acid solution of 0.5% to 5%, the silicon oxide film 108 of approximately 0.5 nm to 0.8 nm is formed in an oxygen atmosphere. Furthermore, a hafnium silicon oxide film (HfSiO film) having a film thickness of approximately 2.0 nm is formed on the silicon substrate 101 using tetrakisdiethylaminohafnium, diethylsilane, and oxygen.

After nitrogen is doped in the HfSiO film in a nitrogen plasma atmosphere or an NH₃ atmosphere, a thermal processing is performed to modify the HfSiO film into the hafnium silicon oxynitride (HfSiON) film 109. Thus, the structure shown in FIG. 47 is obtained. The HfSiON film 109 and the silicon oxide film 108 function as the gate dielectric layer.

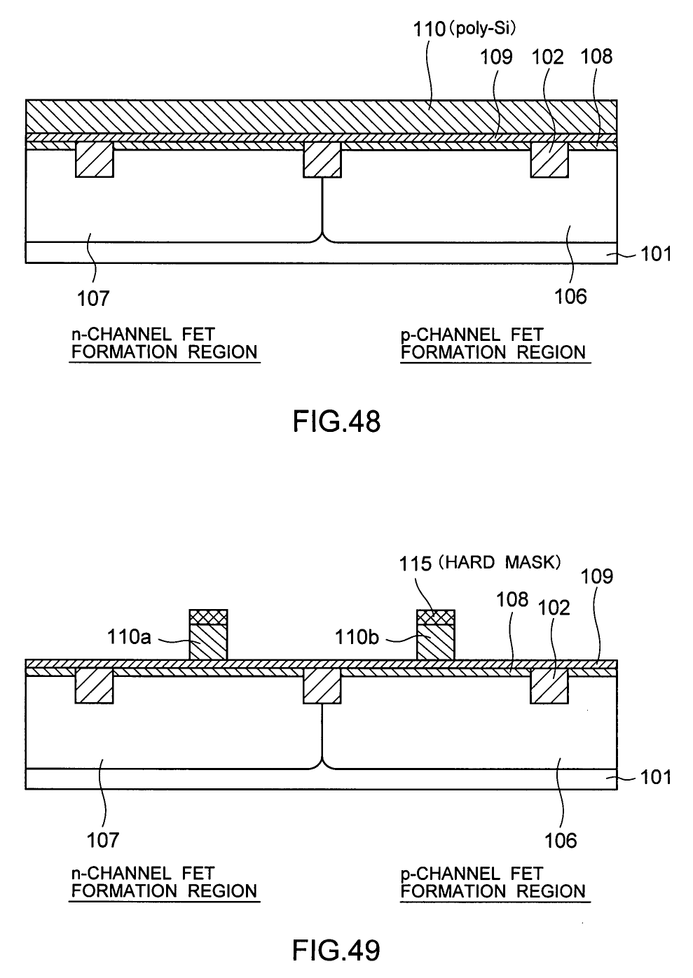

Next, as shown in FIG. 48, the polysilicon film 110 is deposited on the HfSiON film 109 as a gate electrode material by CVD.

Next, a silicon oxide film, a silicon nitride film, or a lamination film of these materials (hereinafter, “mask material”) 115 is deposited on the polysilicon film 110. Subsequently, patterning is performed on the mask material 115 to form an electrode pattern by photolithography.

As shown in FIG. 49, the polysilicon film 110 is processed into a gate electrode pattern using the mask material 115 as a hard mask. The gate electrode of the n-channel MISFET obtained as a result is represented by 110a, and the gate electrode of the p-channel MISFET is represented by 110b.

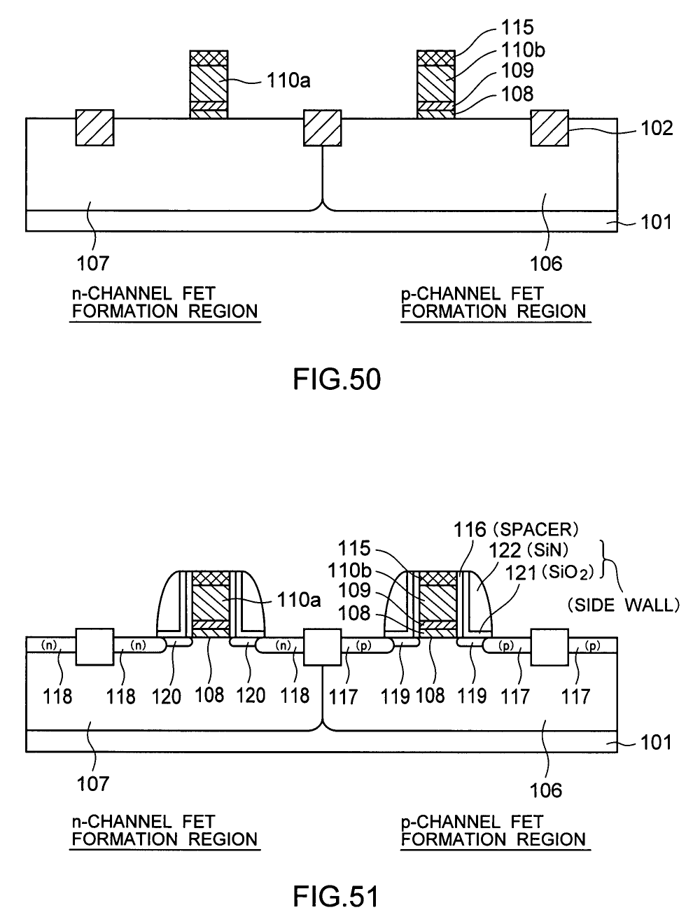

Furthermore, as shown in FIG. 50, the HfSiON film 109 is removed with the dilute hydrofluoric acid solution or the like using the mask material 115 and the gate electrodes 110a and 110b as a mask. At this time, concentration of hydrofluoric acid and etching time are chosen such that the mask material 115 is not completely etched. Specifically, the etching solution and the etching time are appropriately determined based on material type and thickness of a high dielectric constant insulation film (HfSiON film 109 in the fourth embodiment). For example, it is preferable that hydrofluoric acid concentration is 1% or lower, and the etching time is 300 seconds or less. Since the silicon oxide film 108 has very thin thickness of approximately 0.5 nm to 0.8 nm, the silicon oxide film 108 is usually removed at the time of etching of the HfSiON film 109. However, there is no problem even if the silicon oxide film 108 remains on the surface of the silicon substrate 101. The high dielectric constant insulation film is of a material having a relative permittivity higher than that of the silicon oxide film.

Next, sides of the gate electrode materials 110a and 110b and the surface of the silicon substrate 101 are slightly oxidized. The oxidization process was carried out in an oxygen atmosphere of approximately 0.2% for 5 seconds at a temperature of 1000° C. Film thickness of an oxide film formed by this process was approximately 2 nm. Thereafter, as shown in FIG. 51, the offset spacers 116 formed by silicon oxide or silicon nitride are formed by CVD and RIE. Furthermore, the sidewall spacers 121 and 122 formed with a silicon oxide film or a silicon nitride film are formed by CVD and RIE.

Next, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermally processed to activate the impurity, thereby the p-type source/drain diffusion layer 117 and the n-type source/drain diffusion layer 118 are formed as shown in FIG. 51.

After the sidewalls 121 and 122 are removed, the n-channel MISFET formation region is covered with a photoresist (not shown) by photolithography, and a p-type impurity (for example, boron) is ion-implanted in the p-channel MISFET formation region. Similarly, the p-channel MISFET formation region is covered with a photoresist by photolithography, and an n-type impurity (for example, phosphorus or arsenic) is ion-implanted in the n-channel MISFET formation region.

After the photoresist is removed, the silicon substrate 101 is thermally processed to activate the impurity, thereby the p-type extension region 119 and the n-type extension region 120 are formed as shown in FIG. 51. Hollow implantation can be subsequently performed to suppress the short channel effect.

Next, as shown in FIG. 51, the sidewalls 121 and 122 are formed again on the sides of the gate electrode materials 110a and 110b by CVD and RIE. While in the fourth embodiment, a two-layer lamination film of a silicon oxide film and a silicon nitride film is used as the sidewall, a three-layer lamination film formed by laminating silicon oxide films and/or silicon nitride films can also be used as the sidewall. The structure of the sidewall should be formed according to a device.

While in the fourth embodiment, the ion implantation of the extension diffusion layer is performed after the ion implantation of the source/drain diffusion layer as described above, the extension diffusion layer can be formed before the formation of the source/drain diffusion layer. In this case, it becomes unnecessary to remove the sidewalls 121 and 122.

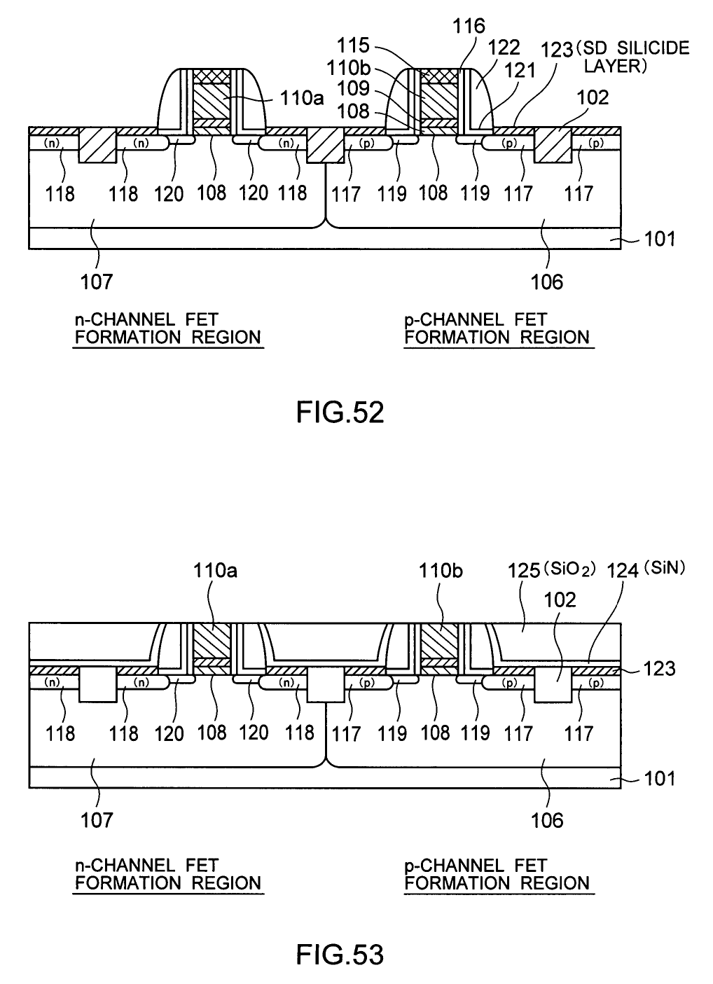

As shown in FIG. 52, the source silicide film/drain silicide film 123 (hereinafter, “SD silicide layer”) is then formed on surfaces of the source/drain diffusion layers 117 and 118 in a self-aligning manner. A material of the SD silicide layer 123 can be, for example, any one of NiPtSix, NiSix, PtSi (used in the p-channel MISFET region), ErSi (used in the n-channel MISFET region), NiErSi (used in the n-channel MISFET region), or the like.

Next, as shown in FIG. 53, the silicon nitride film 124 is deposited by CVD, and further, the silicon oxide film 125 is deposited thereover. The silicon nitride film 124 functions as an etching stopper. Subsequently, the silicon oxide film 125 is planarized by CMP (Chemical Mechanical Polishing), dry etching, or wet etching. The silicon oxide film 125, the silicon nitride film 124, and the hard mask 115 are polished to expose top surfaces of the gate electrodes 110a and 110b.

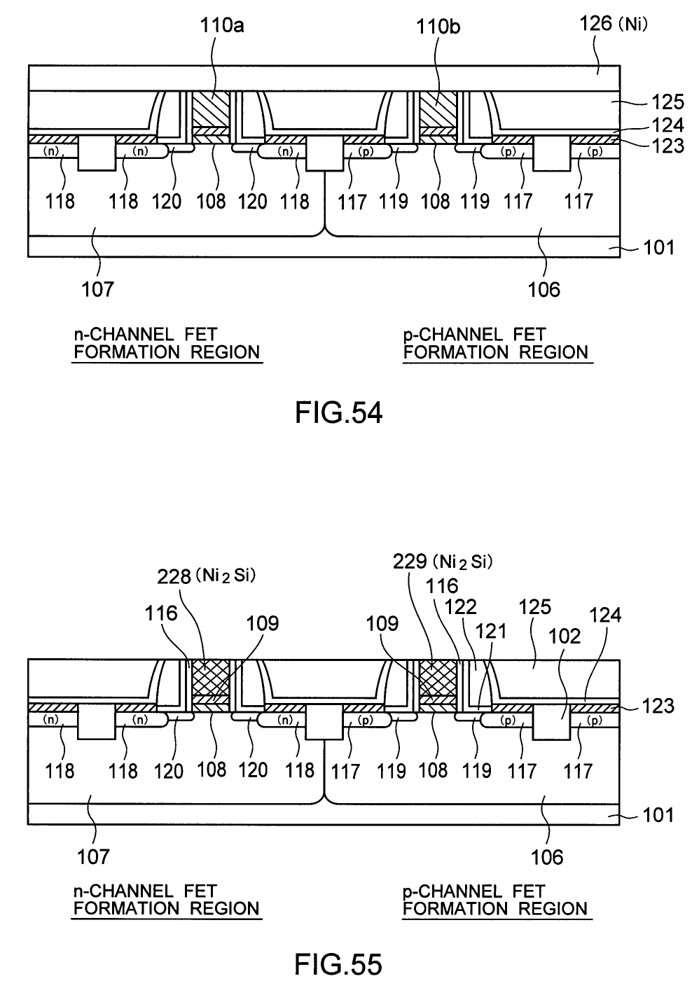

Subsequently, as shown in FIG. 54, the nickel film 126 is deposited. Film thickness of the nickel film 126 is within a range of 1.1 to 1.4 times as thick as thickness of the gate electrodes 110a and 110b. The nickel film 126 and the gate electrodes 110a and 110b are caused to be reacted at a temperature of 400° C. to 500° C., thereby the gate electrodes 110a and 110b are fully silicided. Thermal processing time in this siliciding process is 30 seconds to 300 seconds assuming that film thickness of the nickel film 126 is 50 nm to 160 nm and a temperature condition is 400° C. to 500° C. More specifically, when the film thickness of the gate electrodes 110a and 110b is approximately 50 nm, required film thickness of the nickel film 126 is a range of 55 nm to 70 nm to fully silicide the gate electrodes 110a and 110b. Such gate electrodes 110a and 110b and the nickel film 126 are thermally processed at a temperature of 400° C. for approximately 260 seconds. Thus, the gate electrodes 110a and 110b become nickel silicide having a composition of Ni₂Si. As a result, the structure shown in FIG. 55 is obtained.

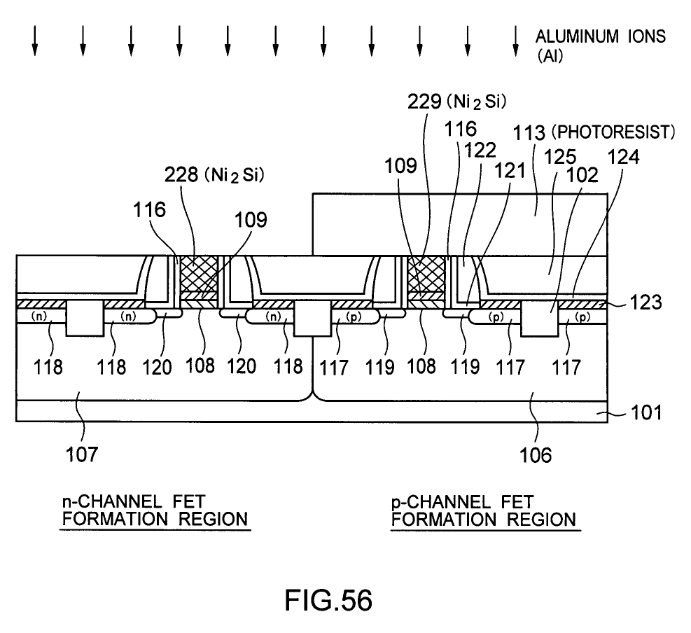

Next, as shown in FIG. 56, the p-channel MISFET region is coated with the photoresist 113. Using the photoresist 113 as a mask, aluminum is ion-implanted. Accordingly, aluminum ion is implanted in the gate electrode of the n-channel MISFET without being implanted in the gate electrode 229 in the p-channel MISFET region.

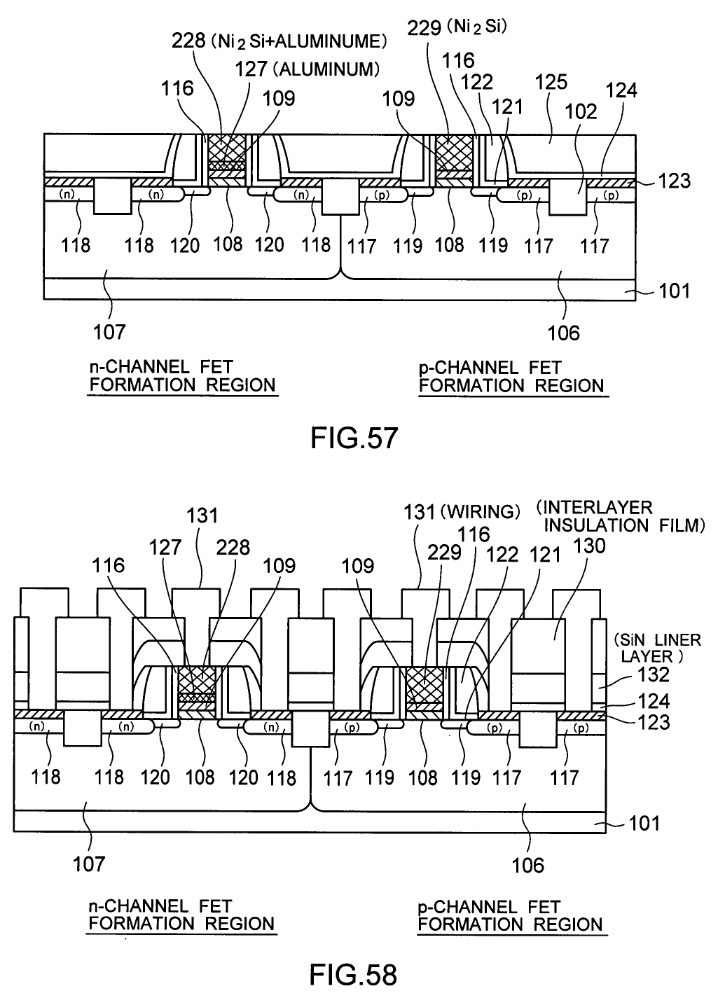

The structure shown in FIG. 56 is then thermally processed at a temperature of 350° C. to 550° C. By this thermal processing, aluminum is segregated to the bottom surface of the gate electrode 228. As a result, as shown in FIG. 57, the aluminum layer 127 is formed at the bottom of the gate electrode 228.

After removing the silicon oxide 125, as shown in FIG. 58, by a known method, the SiN liner layer 132 and the inter-layer insulation film 130 are deposited. A contact is formed in the inter-layer insulation film 130. Wirings 131 and the like are formed. The inter-layer insulation film 130 can be deposited, a contact can be formed in the inter-layer insulation film 130, and the wiring 131 and the like can be formed without removing the silicon oxide film 125.

By annealing with a forming gas in a later process, the semiconductor device according to the fourth embodiment is completed. The structure of the semiconductor device according to the fourth embodiment is the same as that of the semiconductor device according to the first embodiment. Therefore, the semiconductor device according to the fourth embodiment has the equivalent work function as that shown in FIG. 23. Accordingly, the fourth embodiment achieves the similar effects to those of the first embodiment.

While in the fourth embodiment, HfSiON is used as the gate dielectric film, HfSiO can be used as the gate dielectric film instead of HfSiON. Furthermore, by replacing Hf with Zr, ZrSiO or ZrSiON can also be used as the gate dielectric film. Moreover, HfZrSiO or HfZrSiON containing both Hf and Zr can also be used as the gate dielectric film. Such gate dielectric films can further contain Ti, La, or Ta.

HfSiON is superior in thermal resistance to HfSiO. However, by shortening the time of the thermal processing in the manufacturing processes, it becomes possible to use HfSiO as the gate dielectric film.

### Fifth Embodiment

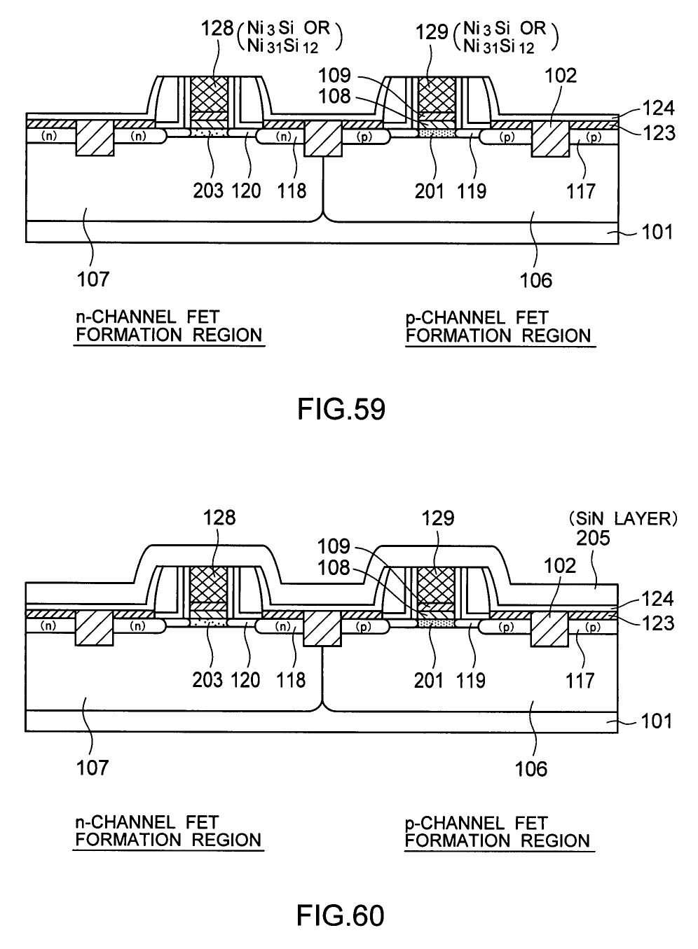

FIGS. 59 to 63 are cross-sections showing a manufacturing method of a semiconductor device according to a fifth embodiment of the present invention. The semiconductor device manufactured according to the fifth embodiment includes gate electrodes composed of Ni₃Si or Ni₃₁Si₁₂.

The processes shown in FIGS. 24 to 36 in the second embodiment are performed. Unreacted nickel is then removed. Thus, the structure shown in FIG. 59 is obtained. The silicon nitride film 125 need not necessarily be provided as shown in FIG. 59.

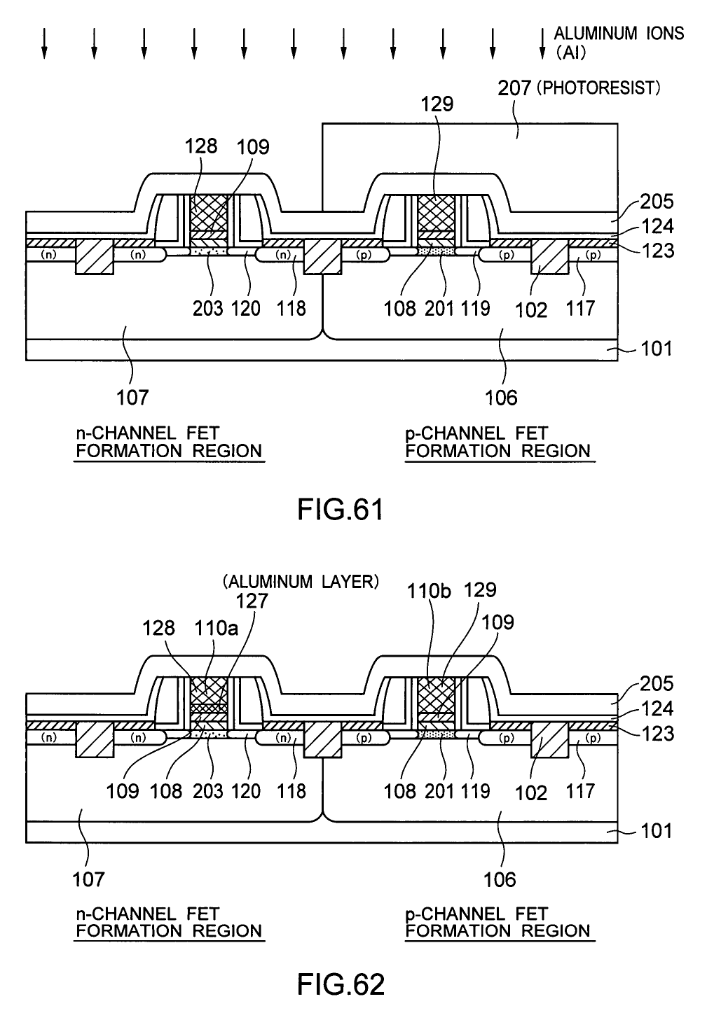

Thereafter, as shown in FIG. 60, the silicon nitride film 205 is deposited. Subsequently, as shown in FIG. 61, the p-channel MISFET region is coated with the photoresist 207. Aluminum ion is implanted in the n-channel MISFET region using the photoresist 207 as a mask.

Furthermore, as shown in FIG. 62, by thermally processing, the aluminum layer 127 is segregated to the bottom portion (between the bottom surface of the gate electrode 128 and the top surface of the HfSiON film 109) of the gate electrode 128 of the n-channel FET region. The silicide layer 128 on this aluminum layer 127 becomes nickel silicide containing aluminum and having a composition of Ni₃Si or Ni₃₁Si₁₂.

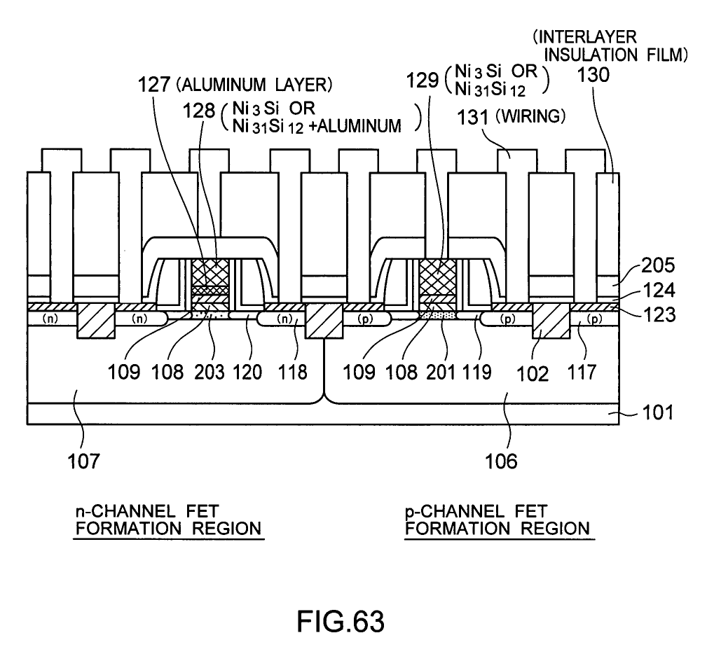

Thereafter, as shown in FIG. 63, by a known method, the inter-layer insulation film 130 is deposited. A contact is formed in the inter-layer insulation film 130. The wiring 131 and the like are formed.

By annealing with a forming gas in a later process, the semiconductor device according to the fifth embodiment is completed. The structure of the semiconductor device according to the fifth embodiment is the same as that of the semiconductor device according to the second embodiment. Therefore, the semiconductor device according to the fifth embodiment has the equivalent work function as that shown in FIG. 43. Accordingly, the fifth embodiment achieves the similar effects to those of the second embodiment.

While in the fifth embodiment, HfSiON is used as the gate dielectric film, HfSiO can be used as the gate dielectric film instead of HfSiON. Furthermore, by replacing Hf with Zr, ZrSiO or ZrSiON can also be used as the gate dielectric film. Moreover, HfZrSiO or HfZrSiON containing both Hf and Zr can also be used as the gate dielectric film. Such gate dielectric films can further contain Ti.

HfSiON is superior in thermal resistance to HfSiO. However, by shortening the time of the thermal processing in the manufacturing processes, it becomes possible to use HfSiO as the gate dielectric film.

Also in the fourth embodiment and fifth embodiments, the SD silicide layer 123 can be formed with NiSi (nickel monosilicide) containing platinum, similarly to the third embodiment. Since the SD silicide layer 123 contains Pt, agglomeration is not caused. Therefore, a failure such as junction leakage does not occur in the semiconductor device according to the fourth and fifth embodiments.

1. A semiconductor device comprising:
a semiconductor substrate;
a gate dielectric film provided on the semiconductor substrate and containing Hf, Si, and O or containing Zr, Si and O;
a gate electrode of an n-channel FET provided on the gate dielectric film, the gate electrode being made of nickel silicide containing nickel at a higher content than silicon;
an aluminum layer provided at a bottom portion of the gate electrode of the n-channel FET; and
a gate electrode of a p-channel FET provided on the gate dielectric film, the gate electrode being made of nickel silicide containing nickel at a higher content than silicon.

2. The semiconductor device according to claim 1, wherein
the gate electrode of an n-channel FET and the gate electrode of a p-channel FET is made of Ni₃Si, Ni₃₁Si₁₂ or Ni₂Si.

3. The semiconductor device according to claim 1, wherein
a channel portion of an n-channel FET contains nitrogen,
a channel portion of a p-channel FET contains fluorine.

4. The semiconductor device according to claim 2, wherein
a channel portion of an n-channel FET contains nitrogen,
a channel portion of a p-channel FET contains fluorine.

5. The semiconductor device according to claim 1 further comprising:
source silicide layers provided on sources of the n-type FET and the p-type FET and containing platinum; and
drain silicide layers provided on drains of the n-type FET and the p-type FET and containing platinum.

6. The semiconductor device according to claim 2 further comprising:
source silicide layers provided on sources of the n-type FET and the p-type FET and containing platinum; and
drain silicide layers provided on drains of the n-type FET and the p-type FET and containing platinum.

7. The semiconductor device according to claim 3 further comprising:
source silicide layers provided on sources of the n-type FET and the p-type FET and containing platinum; and
drain silicide layers provided on drains of the n-type FET and the p-type FET and containing platinum.

8. A manufacturing method of a semiconductor device comprising:
forming a gate dielectric film containing Hf, Si, and O or containing Zr, Si and O on a semiconductor substrate;
depositing a gate electrode material made of polysilicon or amorphous silicon on the gate dielectric film;
forming a gate electrode by processing the gate electrode material into a gate electrode pattern;
depositing a nickel film on the gate electrode;
siliciding the gate electrode with the nickel film so that a composition of the gate electrode becomes Ni_{X}Si_{Y} where X>Y;
depositing aluminum on the gate electrode in an n-channel FET formation region; and
forming an aluminum layer at a bottom portion of the gate electrode of an n-channel FET by causing the aluminum to segregate to the bottom portion of the gate electrode in the n-channel FET formation region by a thermal processing.

9. The manufacturing method of a semiconductor device according to claim 8, wherein
the aluminum has a thickness of 5% to 40% of a thickness of the gate electrode at the time of deposition of the aluminum.

10. The manufacturing method of a semiconductor device according to claim 8, wherein
the gate electrode of an n-channel FET and the gate electrode of a p-channel FET is made of Ni₃Si, Ni₃₁Si₁₂ or Ni₂Si.

11. The manufacturing method of a semiconductor device according to claim 9, wherein
the gate electrode of an n-channel FET and the gate electrode of a p-channel FET is made of Ni₃Si, Ni₃₁Si₁₂ or Ni₂Si.

12. The manufacturing method of a semiconductor device according to claim 8 further comprising:
before formation the gate electrode,
introducing nitrogen to a channel portion of the n-type FET; and
introducing fluorine to a channel portion of the p-type FET.

13. The manufacturing method of a semiconductor device according to claim 9 further comprising:
before formation the gate electrode,
introducing nitrogen to a channel portion of the n-type FET; and
introducing fluorine to a channel portion of the p-type FET.

14. The manufacturing method of a semiconductor device according to claim 8 further comprising:
forming source silicide layers containing platinum on sources of the n-type FET and the p-type FET and forming drain silicide layers containing platinum on drains of the n-type FET and the p-type FET.

15. The manufacturing method of a semiconductor device according to claim 9 further comprising:
forming source silicide layers containing platinum on sources of the n-type FET and the p-type FET and forming drain silicide layers containing platinum on drains of the n-type FET and the p-type FET.

16. A manufacturing method of a semiconductor device comprising:
forming a gate dielectric film containing Hf, Si, and O or containing Zr, Si and O on a semiconductor substrate;
depositing a gate electrode material made of polysilicon or amorphous silicon on the gate dielectric film;
forming a gate electrode by processing the gate electrode material into a gate electrode pattern;
depositing a nickel film on the gate electrode;
siliciding the gate electrode with the nickel film so that a composition of the gate electrode becomes Ni_{X}Si_{Y} where X>Y;
implanting aluminum on the gate electrode in an n-channel FET formation region; and
forming an aluminum layer at a bottom portion of the gate electrode of an n-channel FET by causing the aluminum to segregate to the bottom portion of the gate electrode in the n-channel FET formation region by a thermal processing.

17. The manufacturing method of a semiconductor device according to claim 16, wherein
the gate electrode of an n-channel FET and the gate electrode of a p-channel FET is made of Ni₃Si, Ni₃₁Si₁₂ or Ni₂Si.

18. The manufacturing method of a semiconductor device according to claim 16 further comprising:
before formation the gate electrode,
introducing nitrogen to a channel portion of the n-type FET; and
introducing fluorine to a channel portion of the p-type FET.

19. The manufacturing method of a semiconductor device according to claim 16 further comprising:
forming source silicide layers containing platinum on sources of the n-type FET and the p-type FET and forming drain silicide layers containing platinum on drains of the n-type FET and the p-type FET.
